(19) United States
(12) Patent Application Publication
(10) Pub. No.: US 2025/0301682 A1
(43) Pub. Date: Sep. 25, 2025

(54) SEMICONDUCTOR DEVICE WITH VIA-SHAPED CUT GATE STRUCTURES AND METHODS OF FABRICATION THEREOF

(71) Applicant: TAIWAN SEMICONDUCTOR MANUFACTURING COMPANY, LTD., Hsinchu (TW)

(72) Inventors: Tzu-Ging LIN, Kaohsiung (TW); Shu-Yuan KU, Hsinchu (TW)

(21) Appl. No.: 18/778,999

(22) Filed: Jul. 21, 2024

Related U.S. Application Data
(60) Provisional application No. 63/567,858, filed on Mar. 20, 2024.

(51) Int. Cl. H01L 29/66; H01L 29/78

(52) U.S. Cl. CPC H10D 30/024; H10D 30/6211; H10D 64/017; H10D 64/021

(57) ABSTRACT

Embodiments of the present disclosure provide a semiconductor device with via-shaped cut gate structures. The via shaped cut-gate structures may be formed by a self-aligned patterning process and may minimize parasitic capacitance in the semiconductor device. In some embodiments, a protective layer is deposited over the ILD layer to achieve the self-aligned patterning process. In some embodiments, the protective layer may be formed by recess etching the ILD layer between gate structures and filling the recess with a dielectric layer. In some embodiments, the protective layer may include silicon nitride.

### CROSS-REFERENCE TO RELATED APPLICATIONS

This application claims priority to the U.S. Provisional Patent Application Ser. No. 63/567,858 filed Mar. 20, 2024, which is incorporated by reference in its entirety.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart of a method for manufacturing a semiconductor device according to embodiments of the present disclosure.

FIGS. 2-10, 10A-10D, 11, 12, 12A-12D, 13, 13A-13D, 14A-14D, 15, and 15A-15D schematically illustrate various stages of manufacturing a semiconductor device according to embodiments of the present disclosure.

FIG. 16 is a schematic diagram of a semiconductor device including cut gate structures according to the present disclosure.

FIGS. 17, 18A-18C to 29A-29C schematically illustrate various stages of manufacturing a semiconductor device according to embodiments of the present disclosure.

FIGS. 30A-30C to 33A-33C schematically illustrate various stages of manufacturing a semiconductor device according to embodiments of the present disclosure.

FIGS. 34, 34A-34B, 35, 35A-35B, 36, 36A-36B, 37, 37A-37B, and 38A-38B schematically illustrate various stages of manufacturing a semiconductor device according to embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The foregoing broadly outlines some aspects of embodiments described in this disclosure. While some embodiments described herein are described in the context of nanosheet channel FETs, implementations of some aspects of the present disclosure may be used in other processes and/or in other devices, such as planar FETs, Fin-FETs, Horizontal Gate All Around (HGAA) FETs, Vertical Gate All Around (VGAA) FETs, and other suitable devices. A person having ordinary skill in the art will readily understand other modifications that may be made are contemplated within the scope of this disclosure. In addition, although method embodiments may be described in a particular order, various other method embodiments may be performed in any logical order and may include fewer or more steps than what is described herein. Source/drain region(s) may refer to a source or a drain, individually or collectively dependent upon the context. In the present disclosure, a source/drain refers to a source and/or a drain. A source and a drain are interchangeably used.

The fins may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

When fabricating field effect transistors, gate patterning, such as cut poly (CPO) process and cut metal gate (CMG) process are commonly used to form electric circuits in modern complementary metal oxide semiconductor (CMOS) technology. As device dimension reduces, the dielectric refilling after patterning process may cause huge parasitic capacitance unfavorable for AC application.

Embodiments of the present disclosure provide a semiconductor device with via-shaped cut gate structures. The via shaped cut-gate structures may be formed by a self-aligned patterning process and may minimize parasitic capacitance in the semiconductor device. In some embodiments, a protective layer is deposited over the ILD layer to achieve the self-aligned patterning process. In some embodiments, the protective layer may be formed by recess etching the ILD layer between gate structures and filling the recess with a dielectric layer. In some embodiments, the protective layer may include silicon nitride.

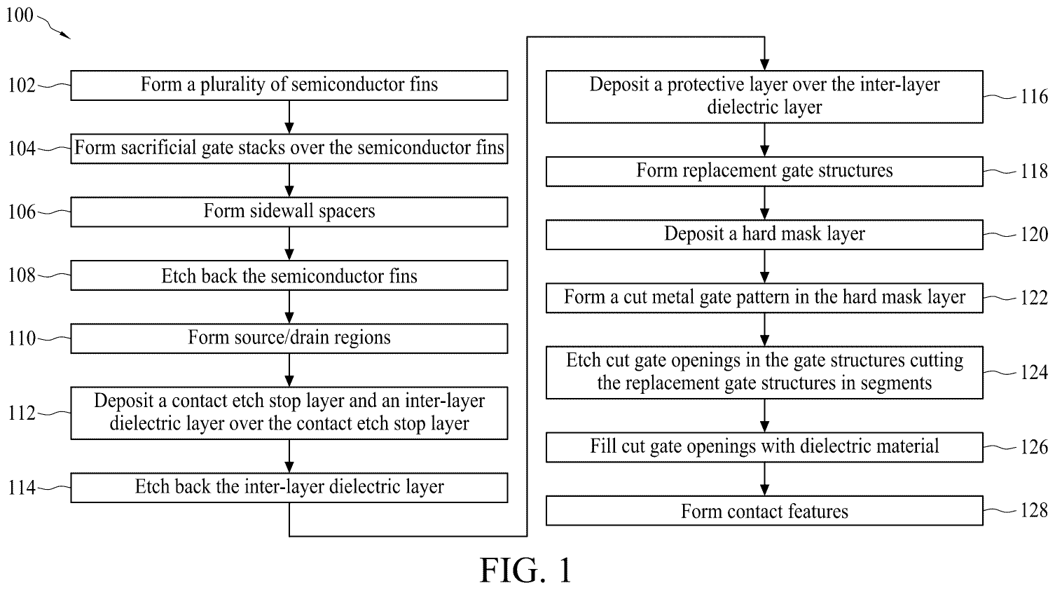

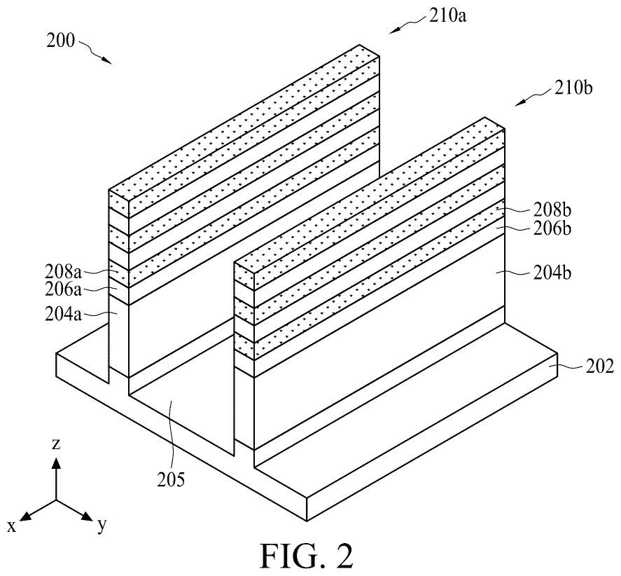

FIG. 1 is a flow chart of a method 100 for manufacturing of a semiconductor device 200 according to embodiments of the present disclosure. FIGS. 2-13 schematically illustrate various stages of manufacturing an exemplary semiconductor device 200 according to embodiments of the present disclosure. Particularly, the semiconductor device 200 may be manufactured according to the method 100 of FIG. 1.

At operation 102 of the method 100, a plurality fin structures are formed on a substrate where a semiconductor device is to be formed, as shown in FIG. 2, which is a schematic perspective view of the semiconductor device 200. A substrate 202 is provided to form the semiconductor device 200 thereon. The substrate 202 may include a single crystalline semiconductor material such as, but not limited to Si, Ge, SiGe, GaAs, InSb, GaP, GaSb, InAlAs, InGaAs, GaSbP, GaAsSb, and InP. The substrate 202 may include various doping configurations depending on circuit design. In FIG. 2, the substrate 202 includes a p-doped region or p-well 204a and an n-doped region or n-well 204b. One or more n-type devices, such as nFETs, are to be formed over and/or within p-well 204a. One or more p-type devices, such as pFETs, are to be formed over and/or within n-well 204b. FIG. 2 shows that the p-well 204a is in a doped local region of a doped substrate, which is not limiting. In other embodiments, the p-well 204a and the n-well 204b may be separated by one or more insulation bodies, e.g., STI.

A semiconductor stack including alternating first semiconductor layers 206a and second semiconductor layers 208a is formed over the p-well 204a to facilitate formation of nanosheet channels in a multi-gate n-type device, such as nanosheet channel nFETs. The first semiconductor layers 206a and second semiconductor layers 208a have different compositions. In some embodiments, the two semiconductor layers 206a and 208a provide for different oxidation rates and/or different etch selectivity. In later fabrication stages, portions of the second semiconductor layers 208a form nanosheet channels in a multi-gate device. Three first semiconductor layers 206a and three second semiconductor layers 208a are alternately arranged as illustrated in FIG. 2 as an example. More or less semiconductor layers 206a and 208a may be included depending on the desired number of channels in the semiconductor device to be formed. In some embodiments, the number of semiconductor layers 206a and 208a is between 1 and 10.

In some embodiments, the first semiconductor layer 206a may include silicon germanium (SiGe). The first semiconductor layer 206a may be a SiGe layer including more than 25% Ge in molar ratio. For example, the first semiconductor layer 206a may be a SiGe layer including Ge in a molar ration in a range between 25% and 50%. The second semiconductor layer 208a may include silicon. In some embodiments, the second semiconductor layer 208a may be un-doped Si layer. Alternatively the second semiconductor layer 208a may be a Ge layer. The second semiconductor layer 208a may include n-type dopants, such as phosphorus (P), arsenic (As), etc.

Similarly, a semiconductor stack including alternating third semiconductor layers 206b and fourth semiconductor layers 208b is formed over the n-well 204b to facilitate formation of nanosheet channels in a multi-gate p-type device, such as nanosheet channel PMOS.

In some embodiments, the third semiconductor layer 206b may include silicon germanium (SiGe). The third semiconductor layer 206b may be a SiGe layer including more than 25% Ge in molar ratio. For example, the third semiconductor layer 206b may be a SiGe layer including Ge in a molar ration in a range between 25% and 50%. The fourth semiconductor layer 208b may include silicon, Ge, a compound semiconductor such as SiC, GeAs, GaP, InP, InAs, and/or InSb, an alloy semiconductor such as SiGe, GaAsP, AlInAs, AlGaAs, InGaAs, GaInP, and/or GaInAsP, or combinations thereof. In some embodiments, the fourth semiconductor layer 208b may be a Ge layer. The fourth semiconductor layer 208b may include p-type dopants, such as boron etc. The material for the interposer, 206a and 206b, may be replaced by silicon oxide or silicon nitride in the following processes in some embodiments.

The semiconductor layers 206a, 206b, 208a, 208b may be formed by a molecular beam epitaxy (MBE) process, a metalorganic chemical vapor deposition (MOCVD) process, and/or other suitable epitaxial growth processes. The semiconductor stacks over the n-well 204b and the p-well 204a may be formed separately using patterning technology.

Fin structures 210a, 210b (collectively 210) are then formed from etching the semiconductor stacks and a portion of the n-well 204b, the p-well 204a underneath respectively, as shown in FIG. 2. The fin structures 210a, 210b are substantially parallel and are separated by trenches 205. Even though, fin structures 210a, 210b for nanosheet FET devices are shown in the semiconductor device 200, embodiments of the present disclosure are also applicable to planar FETs, Fin-FETs, Horizontal Gate All Around (HGAA) FETs, Vertical Gate All Around (VGAA) FETs, and other suitable devices.

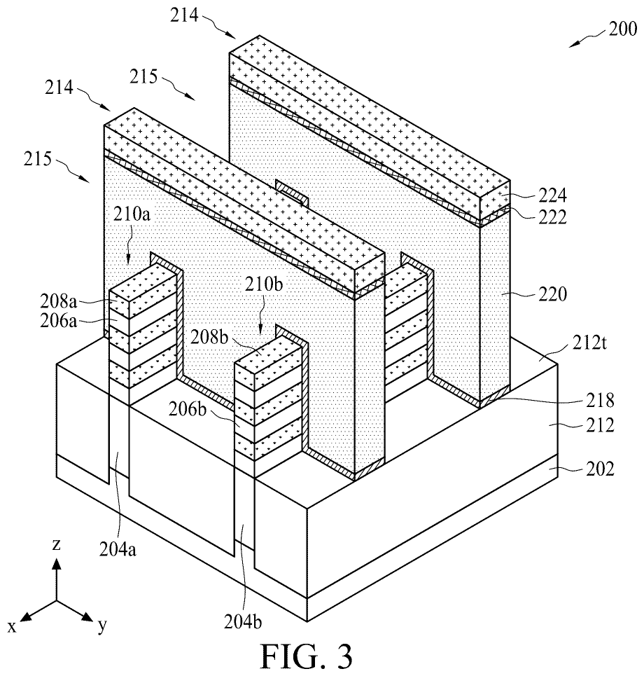

At operation 104, sacrificial gate structures 214 are formed over the isolation layer 212 over the fin structures 210a, 210b, as shown in FIG. 3, which is a schematic view of the semiconductor device 200. An isolation layer 212 is filled in trenches 215 between the fin structures 210a, 210b and then etched back to below the semiconductor stacks of the fin structures 210a, 210b. The isolation layer 212 may be formed by a high-density plasma chemical vapor deposition (HDP-CVD), a flowable CVD (FCVD), or other suitable deposition process. In some embodiments, the isolation layer 212 may include silicon oxide, silicon nitride, silicon oxynitride, fluorine-doped silicate glass (FSG), a low-k dielectric, combinations thereof. In some embodiments, the isolation layer 212 is formed to cover the fin structures 210a, 210b by a suitable deposition process to fill the trenches 205 between the fin structures 210a, 210b, and then recess etched using a suitable anisotropic etching process to expose the active portions of the fin structures 210a, 210b. As shown in FIG. 3, after operation 104, the isolation layer 212 fills bottom portions of the trenches 205 between fin structures 210. Particularly, the stacks of semiconductor layers 206a, 206b, 208a, 208b extend above a top surface 212t of the isolation layer 212.

The sacrificial gate structures 214 are formed over the isolation layer 212 and around the exposed portions of the fin structures 210a, 210b. The sacrificial gate structures 214 are formed over portions of the fin structures 210a, 210b which are to be channel regions. Trenches 215 are formed between neighboring sacrificial gate structures 214. The sacrificial gate structures 214 are substantially perpendicular to the fin structures 210.

The sacrificial gate dielectric layer 218 may be formed conformally over the fin structures 210a, 210b, and the isolation layer 212. In some embodiments, the sacrificial gate dielectric layer 218 may be deposited by a CVD process, a sub-atmospheric CVD (SACVD) process, a FCVD process, an ALD process, a PVD process, or other suitable process. The sacrificial gate dielectric layer 218 may include one or more layers of dielectric material, such as SiO2, SiN, a high-k dielectric material, and/or other suitable dielectric material.

The sacrificial gate electrode layer 220 may be blanket deposited on the sacrificial gate dielectric layer 218. The sacrificial gate electrode layer 220 includes silicon such as polycrystalline silicon or amorphous silicon. The thickness of the sacrificial gate electrode layer is in a range between about 42 nm and about 200 nm. In some embodiments, the sacrificial gate electrode layer 220 is subjected to a planarization operation. The sacrificial gate electrode layer 220 may be deposited using CVD, including LPCVD and PECVD, PVD, ALD, or other suitable process.

Subsequently, the pad layer 222 and the mask layer 224 are formed over the sacrificial gate electrode layer 220. The pad layer 222 may include silicon nitride. The mask layer 224 may include silicon oxide. Next, a processing sequence including patterning and etching is performed on the mask layer 224, the pad layer 222, the sacrificial gate electrode layer 220 and the sacrificial gate dielectric layer 218 to form the sacrificial gate structures 214. Portions of the sacrificial gate electrode layer 220 and the sacrificial gate dielectric layer 218 are sequentially removed using patterns formed in the mask layer 224 to form the sacrificial gate structures 214.

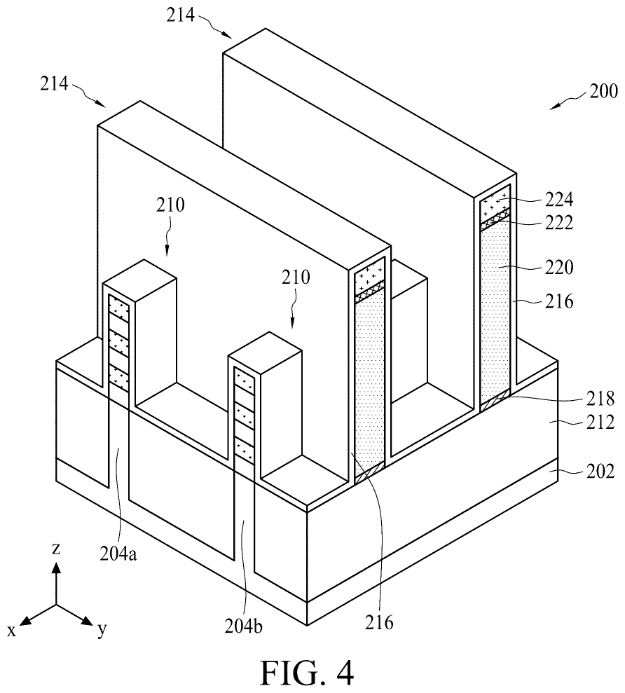

At operation 106, a gate sidewall spacer 216 is formed over the semiconductor device 200, as shown in FIG. 4, which is a schematic perspective view of the semiconductor device 200. After the sacrificial gate structures 214 are formed, the gate sidewall spacer 216 may be deposited over the semiconductor device 200 by a blanket deposition of one or more insulating material. Even though only one layer is shown in FIG. 4, the gate sidewall spacer 216 may include two or more layers of dielectric materials. In some embodiments, the gate sidewall spacer 216 may include one or more insulation material. The gate sidewall spacer 216 may include a silicon nitride-based material, such as SiN, SiON, SiOCN or SiCN and combinations thereof.

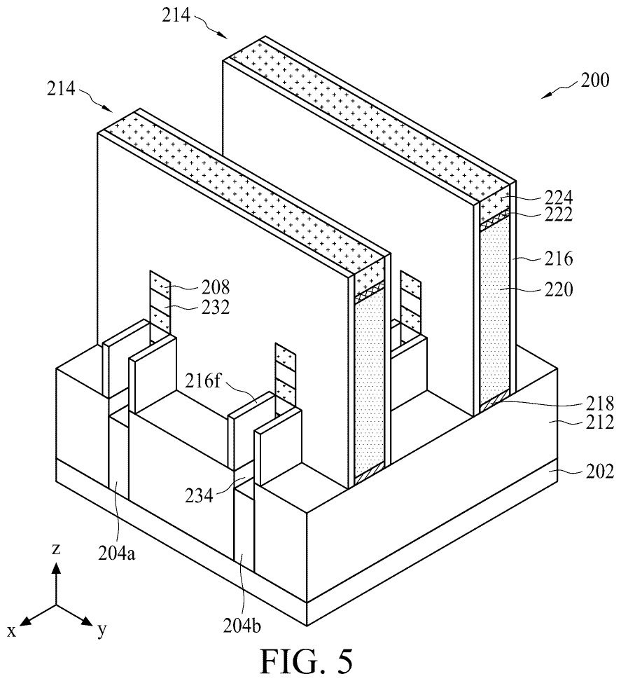

In operation 108, the fin structures 210 not covered by the sacrificial gate structures 214 are etched to expose well portions of each fin structures 210 to form source/drain recesses 234, as shown in FIG. 5. In some embodiments, suitable dry etching and/or wet etching may be used to etch back the semiconductor layers 206, 208, together or separately. A portion of the fin sidewall spacers 216f may remain after the fin structures 210 are recessed. A height of the remaining fin sidewall spacers 216f may be used to control the shape of the subsequently formed epitaxial source/drain regions.

After recess etch of the fin structures 210, inner spacers 232 are formed through the source/drain recesses 234. To form the inner spacers 232, the semiconductor layers 206 under the gate sidewall spacers 216g are selectively etched from the semiconductor layers 208 along the horizontal direction, or x-direction, to form spacer cavities. In some embodiments, the semiconductor layers 206 can be selectively etched by using a wet etchant such as, but not limited to, ammonium hydroxide (NH₄OH), tetramethylammonium hydroxide (TMAH), ethylenediamine pyrocatechol (EDP), or potassium hydroxide (KOH) solutions. After forming the spacer cavities, the inner spacers 232 are formed in the spacer cavities by conformally deposit and then partially remove an insulating layer. The insulating layer can be formed by ALD or any other suitable method. The subsequent etch process removes most of the insulating layer except inside the cavities, resulting in the inner spacers 232.

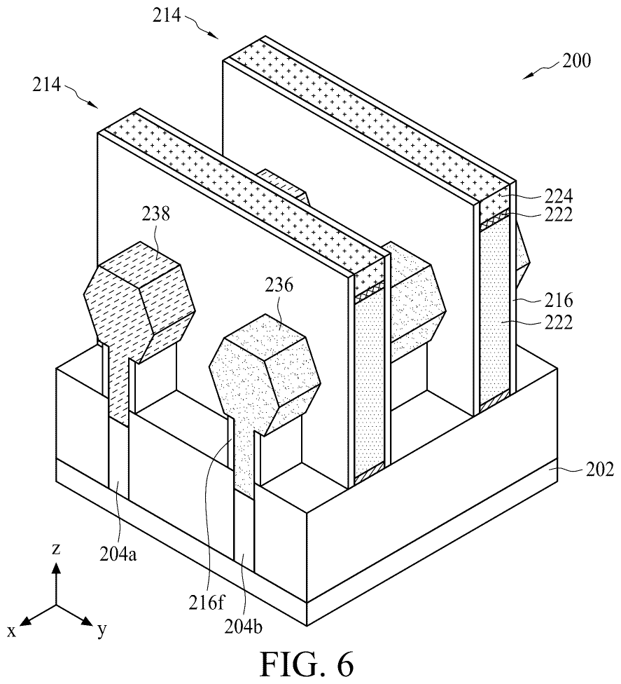

At operation 110, epitaxial source/drain regions 236, 238 are formed, as shown in FIG. 6, which is a schematic perspective view of the semiconductor device 200. In some embodiments, the epitaxial source/drain regions 236, 238 may be for different types of devices and may be formed separately using patterning processes.

In some embodiments, the epitaxial source/drain regions 236 for N-type devices are formed from exposed surfaces of the fin structure 210b. The epitaxial source/drain regions 236 for n-type devices may include one or more layers of Si, SiP, SiC and SiCP. The epitaxial source/drain regions 236 also include N-type dopants, such as phosphorus (P), arsenic (As), etc. In some embodiments, the epitaxial source/drain regions 236 may be a Si layer includes phosphorus (P) dopants. The epitaxial source/drain regions 236 shown in FIG. 6 has a hexagon shape. However, the epitaxial source/drain regions 236 may be other shapes according to the design. The epitaxial source/drain regions 236 may be formed by any suitable method, such as by CVD, CVD epitaxy, molecular beam epitaxy (MBE), or any suitable deposition technique.

The epitaxial source/drain regions 238 may be for P-type devices. The epitaxial source/drain regions 238 may be formed by any suitable method, such as by CVD, CVD epitaxy, molecular beam epitaxy (MBE), or any suitable deposition technique. In some embodiments, epitaxial source/drain regions 238 for the p-type devices may include one or more layers of Si, SiGe, Ge with p-type dopants, such as boron (B), for a p-type device, such as pFET. In some embodiments, the epitaxial source/drain regions 238 may be SiGe material including boron as dopant. The sequence of the formation of epitaxial source/drain for NMOS and PMOS are exchangeable, subject to the requirement for the process requirement. The shape of epitaxial source/drain may be different for NMOS and PMOS, subject to the design of film scheme.

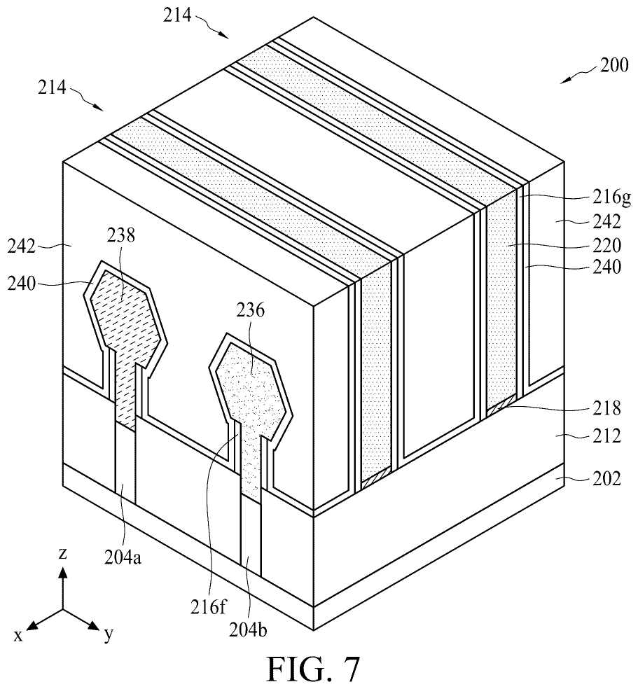

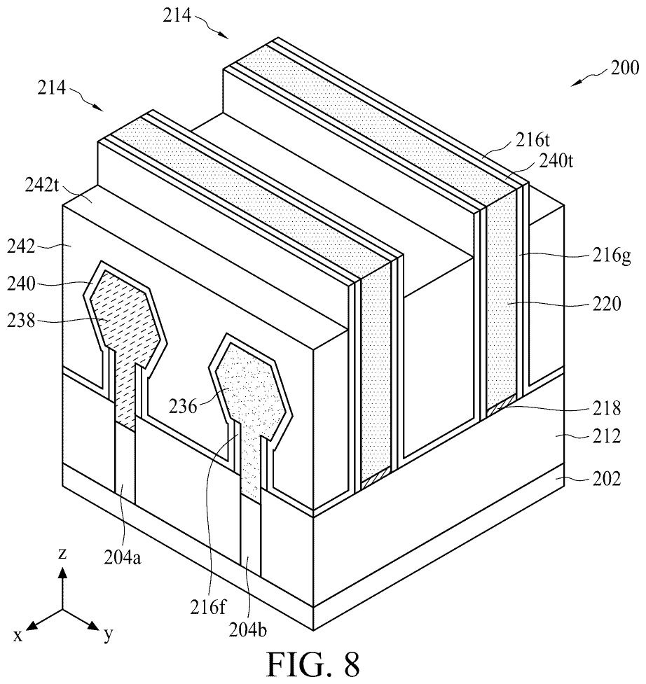

At operation 112, a contact etch stop layer (CESL) 240 and an interlayer dielectric (ILD) layer 242 are conformally formed over the semiconductor device 200, as shown in FIG. 7, which is a schematic perspective view of the semiconductor device 200.

The CESL 240 is formed over exposed surfaces of the semiconductor device 200. The CESL 240 is formed on the epitaxial source/drain regions 236, 238 the gate sidewall spacers 216g, the fin sidewall spacers 216f, and the isolation layer 212. The CESL 240 may include Si₃N₄, SiON, SiCN or any other suitable material, and may be formed by CVD, PVD, or ALD.

The ILD layer 242 is formed over the contact etch stop layer 240. The materials for the ILD layer 242 include compounds comprising Si, O, C, and/or H, such as silicon oxide, SiCOH and SiOC. Organic materials, such as polymers, may be used for the ILD layer 242. In some embodiments, the ILD layer 242 may be formed by flowable CVD (FCV). The ILD layer 242 and the CESL layer 240 protect the epitaxial source/drain regions 236, 238 during the removal of the sacrificial gate structures 214. In some embodiments, after deposition, the ILD layer 242, a planarization process may be performed to expose the sacrificial gate structures 214.

In operation 114, an etch process is performed to selectively etch a top surface 242t of the ILD layer 242 below a top surface 240t of the CESL 240 and a top surface 216t of the gate sidewall spacer 216, as shown in FIG. 8, which is a schematic perspective view of the semiconductor device 200. The ILD layer 242 may be recessed with any suitable etch process, such as dry etch, wet etch, reactive ion etch, chemical oxide removal, dry chemical clean process, or the like. In some embodiment, the ILD layer 242 is etched using a dry etch process, such as a dry etch with etchants such as NH₃/HF, or a plasma dry etching process using a fluorine-based chemistry, such as CF₄, SF₆, CH₂F₂, CHF₃, and/or C₂F₆. After the operation 114, recesses are formed over the ILD layer 242 to allow a protect cap formed thereon in the subsequent process.

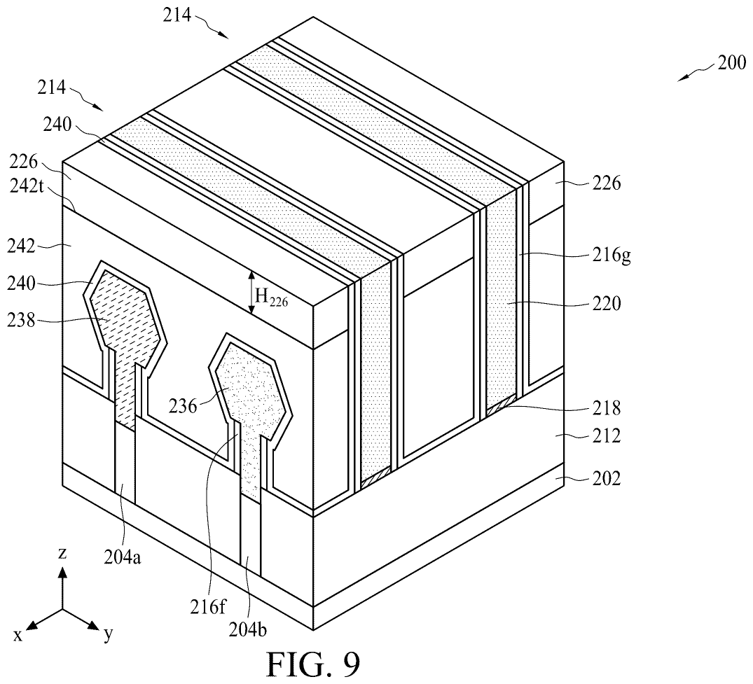

In operation 116, protective caps 226 are formed over the top surface 242t of the ILD layer 242, as shown in FIG. 9, which is a schematic perspective view of the semiconductor device 200. The protective caps 226 may be formed by depositing a protective layer over the ILD layer 242 and the sacrificial gate structures 214 followed by a planarization process to expose the sacrificial gate structures 214. The protective caps 226 are disposed over the top surface 242t of the ILD layer 242 and between the sacrificial gate structures 214. The protective caps 226 are in contact with the top surface 242t of the ILD layer 242 and the CESL 240 on the gate sidewall spacers 216g. As shown in FIG. 9, after formation of the protective caps 226, the ILD layer 242 is covered for the subsequent process.

The protective caps 226 may be formed from a material having etch selectivity with subsequently formed gate structures. In some embodiments, the protective cap 226 may include a nitrogen containing material which has etch selectively with metal material, metal oxide material. In some embodiments, the protective caps 226 are formed from a nitride, such as silicon nitride.

The protective caps 226 have a thickness H₂₂₆ along the z-direction. In some embodiments, the thickness H₂₂₆ is in a range between about 5 nm and about 20 nm. A thickness less than 5 nm may not be sufficient to protect the ILD layer 242 during the subsequent process. A thickness greater than 20 nm may increase aspect ratio of the gate structures during replacement gate process without added protection benefit.

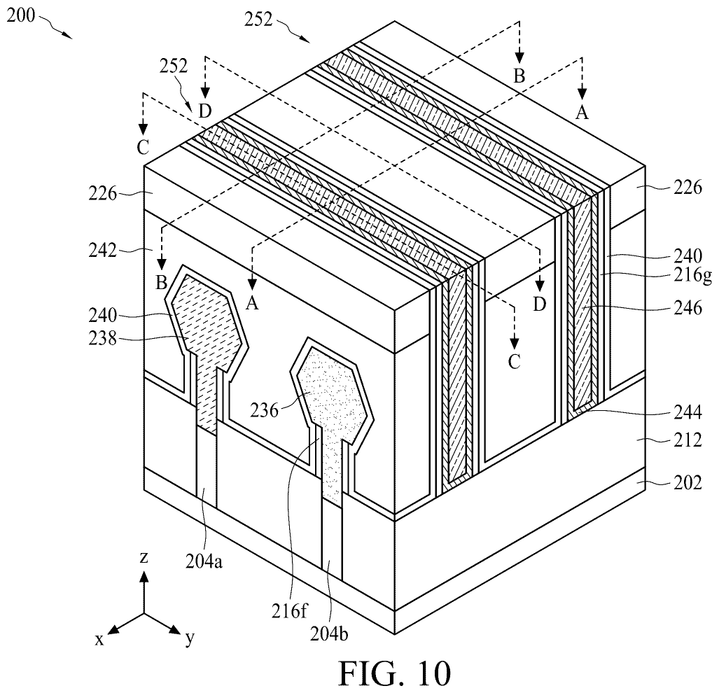

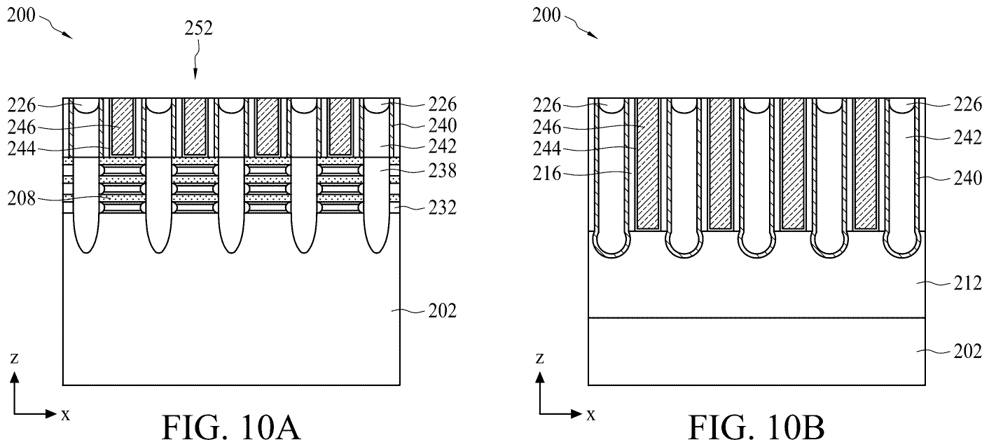

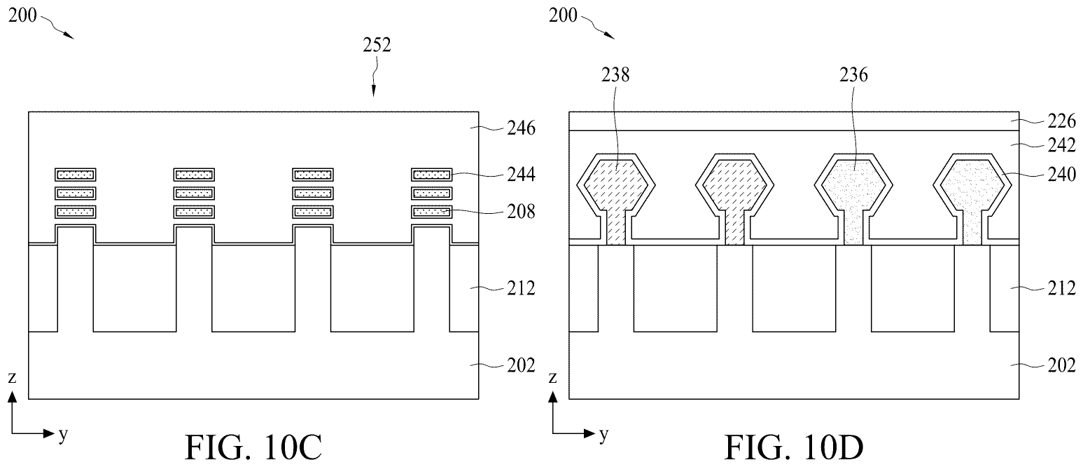

At operation 118, replacement gate structures 252 are formed as shown in FIGS. 10, 10A-10D. FIG. 10 is a perspective view of the semiconductor device 200. FIGS. 10A, 10B, 10C, and 10D are cross sectional views of the semiconductor device 200 along A-A, B-B, C-C, and D-D lines respectively. It should be noted that there are two replacement gate structures 252 are shown across two semiconductor fin structures 210 in FIG. 10 while there are four replacement gate structures 252 are shown across four semiconductor fin structures 210 in FIGS. 10A-10D.

In some embodiments, the sacrificial gate dielectric layer 218 and the sacrificial gate electrode layer 220 are removed using dry etching, wet etching, or a combination. The semiconductor layers 206a, 206b are exposed and subsequently removed resulting in gate cavities surrounding nanosheets of the semiconductor layers 208a, 208b. Replacement gate structures 252 are then filled in the gate cavities. The replacement gate structures 252 may include a gate dielectric layer 244 and a gate electrode layer 246.

The gate dielectric layer 244 is formed on exposed surfaces in the gate cavities. The gate dielectric layer 244 may have different composition and dimensions for N-type devices and P-type devices and are formed separately using patterned mask layers and different deposition recipes. The gate dielectric layer 244 may include one or more layers of a dielectric material, such as silicon oxide, silicon nitride, or high-k dielectric material, other suitable dielectric material, and/or combinations thereof. Examples of high-k dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-k dielectric materials, and/or combinations thereof. The gate dielectric layer 244 may be formed by CVD, ALD or any suitable method.

The gate electrode layer 246 is formed on the gate dielectric layer 244 to fill the gate cavities. The gate electrode layer 246 may include one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or combinations thereof. In some embodiments, the gate electrode layer 246 may be formed by CVD, ALD, electro-plating, or other suitable method.

After the formation of the gate electrode layer 246, a planarization process, such as a CMP process, is performed to remove excess deposition of the gate electrode material and expose the protective caps 226.

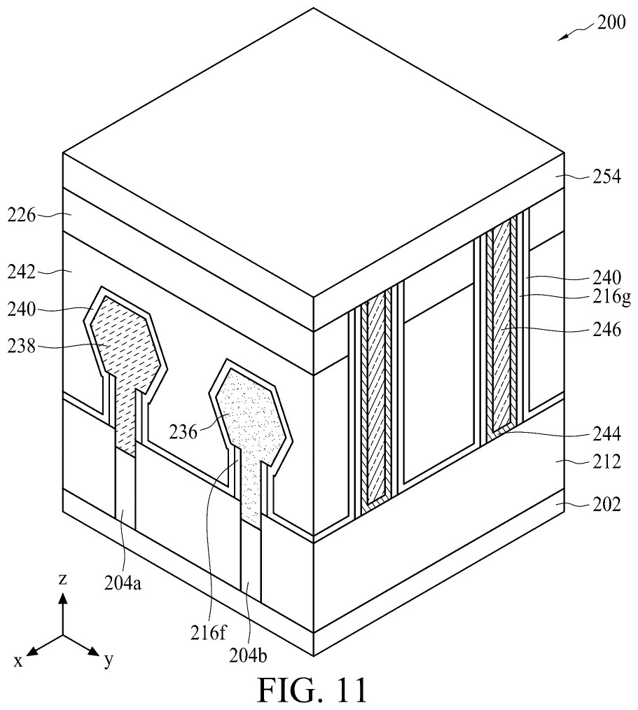

In operation 120, a mask layer 254 is deposited over the replacement gate structures 252 and the protective caps 226, as shown in FIG. 11, which is a perspective view of the semiconductor device 200. The mask layer 254 is configured to use a hard mask layer for forming cut metal gate structures. In some embodiments, the mask layer 254 is a dielectric layer, such as silicon nitride. In other embodiments, the mask layer 254 may include a semiconductor layer, such as amorphous silicon.

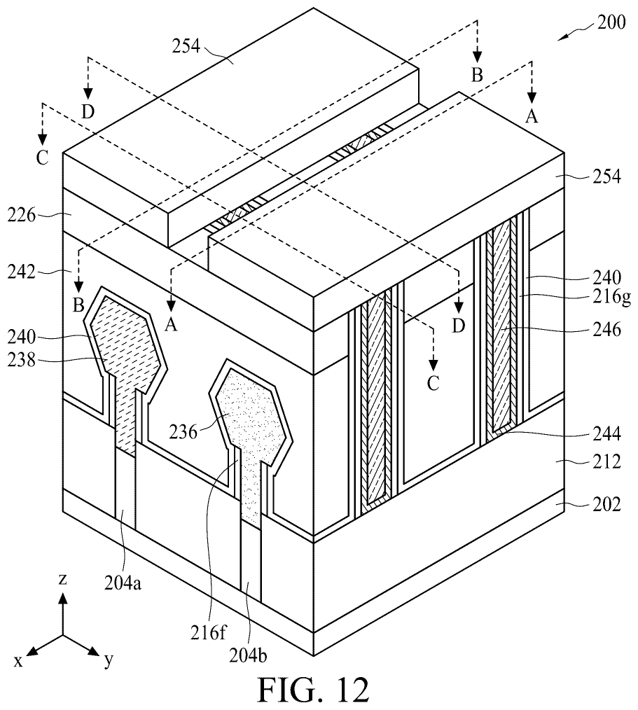

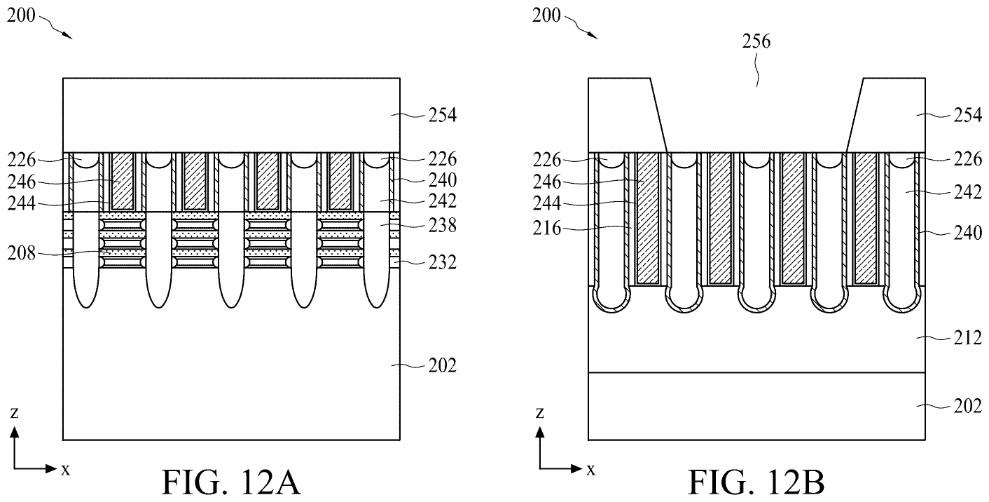

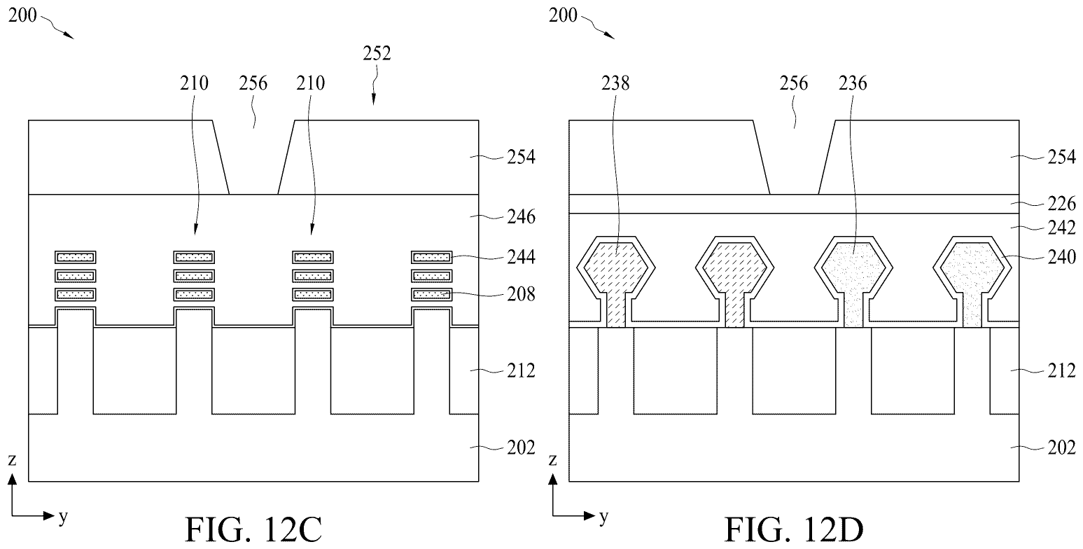

In operation 122, a patterning process is performed to form cut gate pattern 256 in the mask layer 254, as shown in FIGS. 12 and 12A-12D. FIG. 12 is a perspective view of the semiconductor device 200. FIGS. 12A, 12B, 12C, and 12D are cross sectional views of the semiconductor device 200 along A-A, B-B, C-C, and D-D lines respectively.

The cut gate pattern 256 may be formed in the mask layer 254 by depositing and patterning a photoresist layer, such as a tri-layer photoresist (not shown) over the mask layer 254 and etching mask layer 254 through the photoresist layer.

In some embodiments, the cut gate pattern 256 may include one or more elongated openings formed between the semiconductor fin structures 210 to expose one or more replacement gate structures 252 across the semiconductor fin structure 210. As shown in FIGS. 12 and 12C, over the replacement gate structures 252, openings of the cut gate pattern 256 are disposed between two stacks of semiconductor channel layers 208 of two semiconductor fin structures 210 and expose the replacement gate structure 252. Correspondingly, as shown in FIG. 12D, the openings of the cut gate pattern 256 are disposed between two neighboring source/drain regions 236/238, aligned with the ILD layer 242 and exposing the protective cap 226 over the ILD layer 242. In FIG. 12B, the openings of the cut gate pattern 256 expose one or more replacement gate structures 252 to be cut and the protective caps 226 on both sides and in between the exposed replacement gate structures 252. The gate sidewall spacers 216 and the CESL 240 between the replacement gate structures 252 and the protective caps 226.

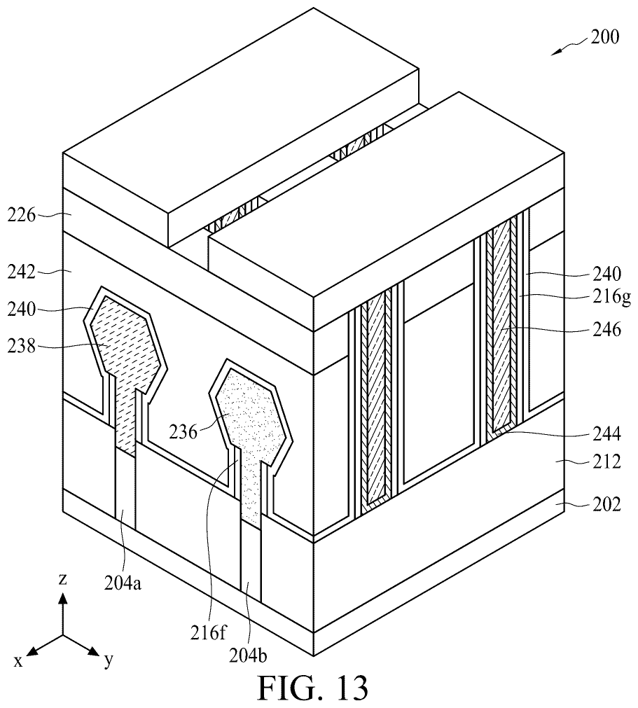

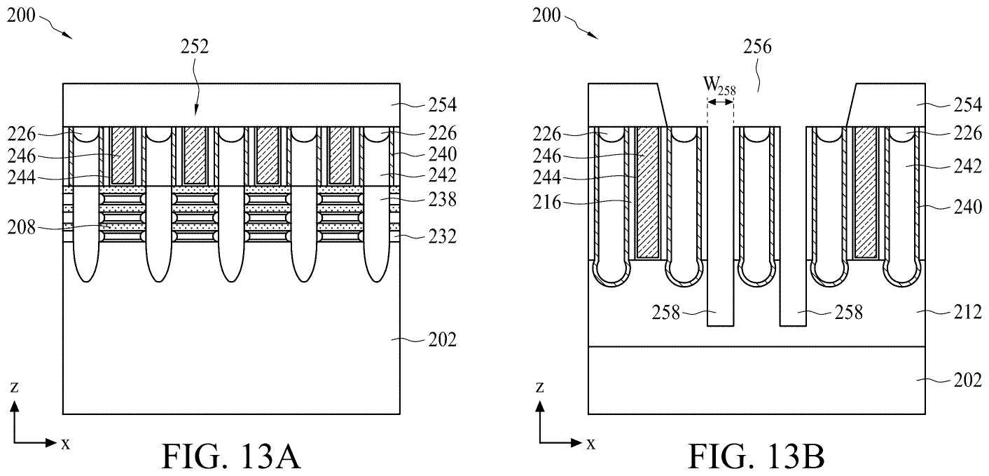

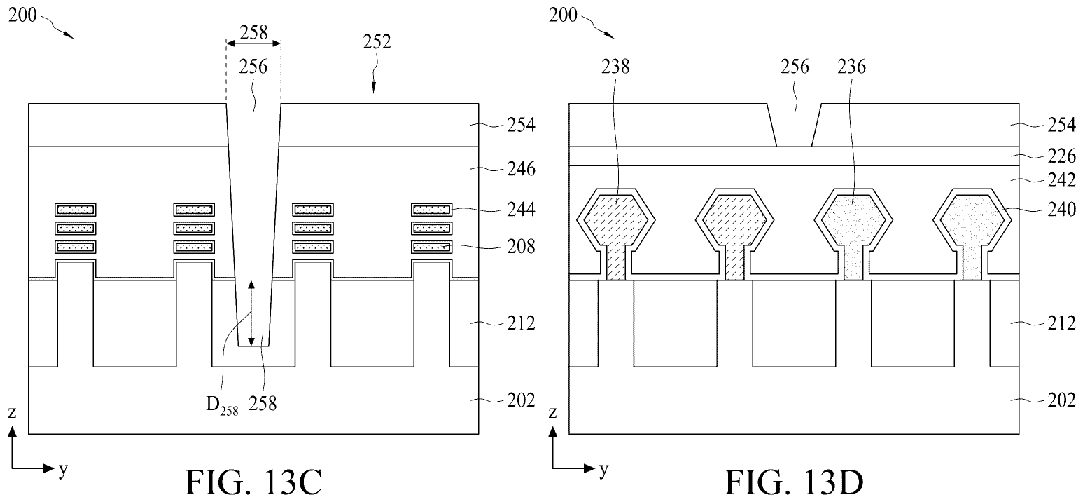

In operation 124, cut gate openings 258 are formed in the replacement gate structures 252, as shown in FIGS. 13, and 13A-13D. FIG. 13 is a perspective view of the semiconductor device 200. FIGS. 13A, 13B, 13C, and 13D are cross sectional views of the semiconductor device 200 along A-A, B-B, C-C, and D-D lines respectively.

The cut gate openings 258 are formed by a self-aligned etch process using the cut gate pattern 256 formed in the mask layer 254. As shown in FIGS. 13B and 13C, the cut gate openings 258 are vias formed through the replacement gate structures 252 and into the isolation layer 212. In some embodiments, one or more etch processing may be performed to selectively remove the gate electrode layer 246 and the gate dielectric layer 244 exposed by the cut gate pattern 256 with the protective caps 226, the CESL 240, and the gate sidewall spacers 216 substantially unaffected.

Even though the cut gate pattern 256 are elongated openings across one or more replacement gate structures 252 and expose on both sides and the between the replacement gate structures 252, the cut gate openings 258 extended from the cut gate pattern 256 are via openings extended between the gate sidewall spacers 216 in the replacement gate structures 252. The cut gate openings 258 cut corresponding gate electrode layer 246 and gate dielectric layer 244 into segments within the replacement gate structure 252, as shown in FIG. 13C, while the ILD layer 242 under the openings of the cut gate pattern 256 remain, as shown in FIGS. 13B and 13D.

As shown in FIG. 13B, the cut gate openings 258 are formed between the gate sidewall spacers 216. In other words, the cut gate openings 258 do not extend through the gate sidewall spacers 216 along the X direction. In some embodiments, the cut gate openings 258 has a Width W₂₅₈ along the x direction.

As shown in FIG. 13C, the cut gate opening 258 cuts through the gate electrode layer 246 and the gate dielectric layer 244 and into the isolation layer 212. In some embodiments, the cut gate opening 258 has a length L₂₅₈ along the y direction. In some embodiments, the length L₂₅₈ is in a range between about 5 nm and about 20 nm. A length less than about 5 nm may not be sufficient enough to provide electric isolation between the gate electrode layer 246 on opposite sides of the cut gate opening 258. A length greater than 20 nm may affect structure integrity of the adjacent semiconductor channel layers 208. The cut gate opening 258 extends into the isolation layer 212 for a depth D₂₅₈ along the z direction. In some embodiments, the depth D₂₅₈ is in a range between about 5 nm and about 70 nm. A substantial recess on STI, D₂₅₈, was usually obtained to avoid any metal residue in cut gate trenches. In some embodiments, the maximum value for D₂₅₈ is below the thickness of STI, therefore the well structure below STI will not be damaged by cut gate processes.

In some embodiments, the cut gate openings 258 may be formed using one or more etching processes. In some embodiments, the etching processes may use etching chemistry configured to selectively remove metal materials in the gate electrode layer 246, oxide layers in the gate dielectric layer 244 and the nitrogen containing materials in the protective caps 226. In some embodiments, the etching chemistry is also selected to have minimal effect on the gate sidewall spacers 216 and the CESL 240. In some embodiments, the etch chemistry may include a chlorine containing gas, such as SiCl4, BCl3, Cl2, CHCl3, CCl4, and/or BCl3, bromine-containing gas, such as HBr and/or CHBr3, an iodine-containing gas, or any suitable gas, or a combination thereof. In some embodiments, the etch process may be a plasma process.

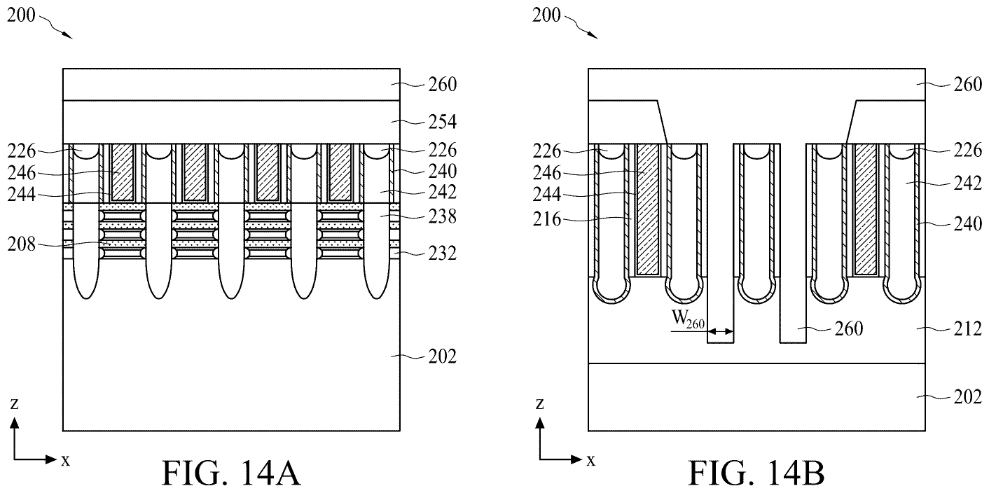

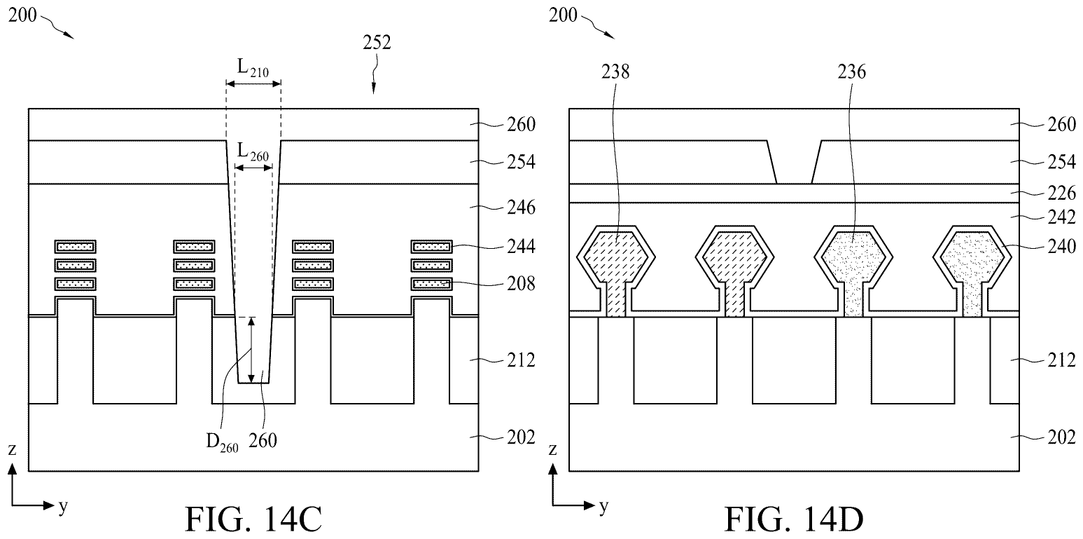

In operation 126, cut gate structures 260 are formed by depositing a dielectric fill material, as shown in FIG. 14A-14D. The dielectric fill material may include any suitable dielectric material. In some embodiments, the dielectric fill material may include one or more low-k dielectric material to provide electrical isolation between segments of the gate electrode layer 246 and sufficient mechanical strength to provide structural integrity in the replacement gate structure 252. In some embodiments, the cut gate structure 260 may include silicon nitride, silicon oxide, or a combination.

As shown in FIGS. 14A-14D, the cut gate structures 260 are via structures limited within the gate sidewall spacers 216 without extending into the ILD layer 242. By limiting the cut gate structures 260 within the replacement gate structures 252, embodiments of the present disclosure avoid forming a dielectric structure between neighboring epitaxial source/drain regions 236/238 and minimizing parasite capacitance within the semiconductor device 200.

The cut gate structure 260 cuts through the gate electrode layer 246 and the gate dielectric layer 244 and into the isolation layer 212. In some embodiments, the cut gate structure 260 has a width W₂₆₀ along the x direction. The width W₂₆₀ is equal to or larger than the distance between the gate sidewall spacers 216 along the x-direction. In some embodiments, the cut gate structure 260 has a length L₂₆₀ along the y direction.

In some embodiments, the length L₂₆₀ is in a range between about 5 nm and about 20 nm. A length less than about 5 nm may not be sufficient enough to provide electric isolation between the gate electrode layer 246 on opposite sides of the cut gate structure 260. A length greater than 20 nm may affect structure integrity of the adjacent semiconductor channel layers 208. In some embodiments, the length L₂₆₀ of the cut gate structure 260 along the Y-direction is about 80 percent to about 90 percent of a length L₂₁₀ between two adjacent semiconductor fin structures 210 for device requiring high density, such as SRAM and ring oscillator. The cut gate structure 260 extends into the isolation layer 212 for a depth D₂₆₀ along the z direction. In some embodiments, the depth D₂₆₀ is in a range between about 5 nm and about 20 nm.

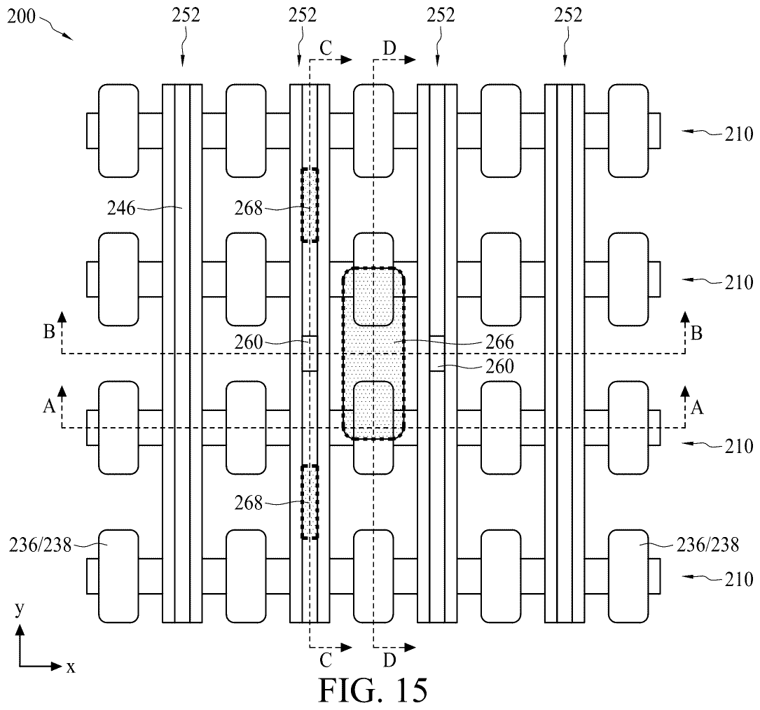

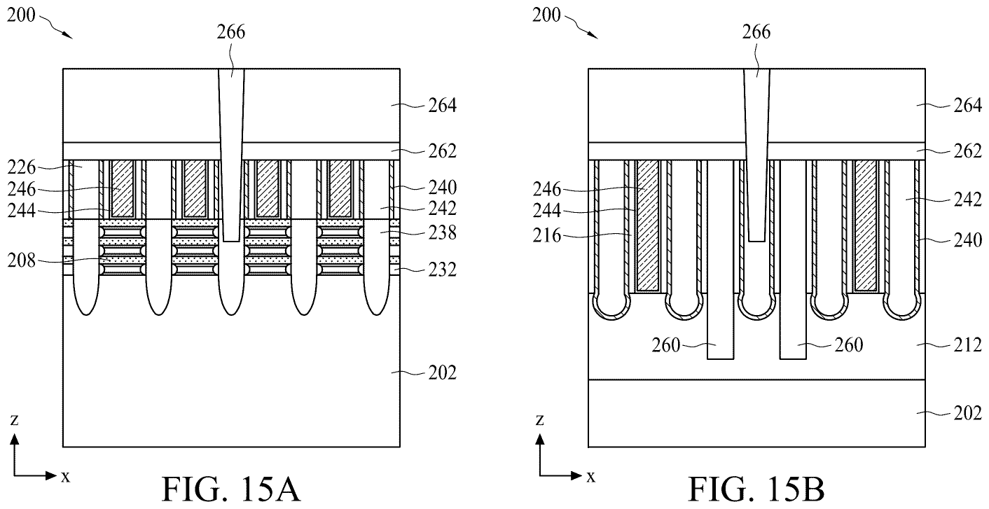

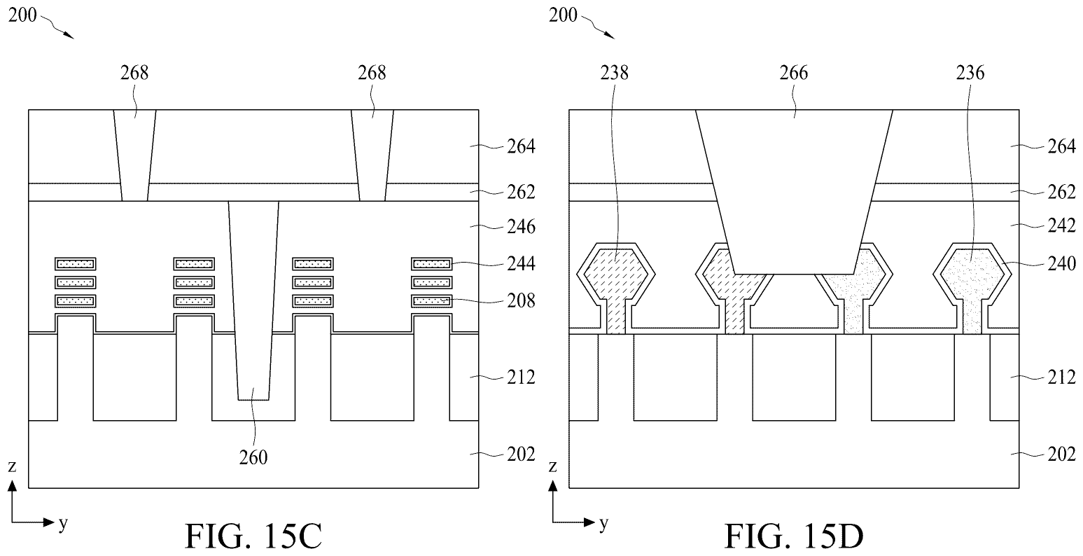

In operation 128, source/drain contact features 266 and the gate contact features 268 are formed, as shown in FIGS. 15, and 15A-15D. FIG. 15 is a schematic plan view of the semiconductor device 200. For clarity, various dielectric materials are not shown in FIG. 15. FIGS. 15A, 15B, 15C, and 15D are cross sectional views of the semiconductor device 200 along A-A, B-B, C-C, and D-D lines in FIG. 15 respectively.

After deposition of the dielectric filling material, a planarization process may be performed to expose the gate electrode layer 246 and the ILD layer 242 for the subsequent process. The protective caps 226 are removed during the planarization process. In some embodiments, an etch stop layer 262 and an ILD layer 264 may then deposited over the gate electrode layer 246 and the ILD layer 242.

To form the source/drain contact features 266, contact holes may be formed through the ILD layer 242, the CESL 240 to expose the epitaxial source/drain regions 236, 238, and subsequently filled with a conductive material. Suitable photolithographic and etching techniques are used to form the contact holes through various layers. After the formation of the contact holes, a silicide layer, not shown, is selectively formed over surfaces of the epitaxial source/drain regions 236, 238 exposed by the contact holes. The silicide layer may be formed by depositing a metal source layer to cover exposed surfaces including the exposed surfaces of the epitaxial source/drain regions 236, 238 and performing a rapid thermal annealing process. In some embodiments, the metal source layer includes a metal layer selected from W, Co, Ni, Ti, Mo, and Ta, or a metal nitride layer selected from tungsten nitride, cobalt nitride, nickel nitride, titanium nitride, molybdenum nitride, and tantalum nitride. After the formation of the metal source layer, a rapid thermal anneal process is performed. During the rapid anneal process, the portion of the metal source layer over the epitaxial source/drain regions 236, 238 reacts with silicon in the epitaxial source/drain regions 236, 238 to form the silicide layer. Unreacted portion of the metal source layer is then removed. In some embodiments, the silicide layer includes one or more of WSi, CoSi, NiSi, TiSi, MoSi, and TaSi.

After formation of the silicide layer 248, a conductive material is deposited to fill contact holes and form the source/drain contact features 266. Optionally, a barrier layer may be formed in the contact holes prior to forming the source/drain contact features 266. In some embodiments, the conductive material layer for the gate contact may be formed by CVD, PVD, plating, ALD, or other suitable technique. In some embodiments, the conductive material for the source/drain contact features 250 includes TIN, TaN, Ta, Ti, Hf, Zr, Ni, W, Co, Cu, Ag, Al, Zn, Ca, Au, Mg, Mo, Cr, or the like. Subsequently, a CMP process is performed to remove a portion of the conductive material layer above a top surface of the ILD layer 264.

Similarly, to form the gate contact features 268, contact holes may be formed through the ILD layer 264 and etch stop layer 262 to expose the gate electrode layer 246, and subsequently filled with a conductive material.

Embodiments of the present disclosure provide a method for forming via-shaped cut gate structures within gate sidewall spacers of the individual gate structures, instead of extending into the ILD layer and between the neighboring source/drain regions. The via-shaped cut gate structures may be facilitated by adding protective caps over the ILD layer and without changing circuit design or mask patterns used in traditional line-shaped cut gate structures.

As shown in FIG. 15 and FIG. 15D, the cut gate structures 260 are via features disposed within the gate sidewall spacers 216 without extending between neighboring source/drain regions 236/238, therefore, minimizing parasitic capacitance between the neighboring source/drain regions 236/238.

As shown in FIG. 15 and FIG. 15B, because the cut gate structures 260 do not extend into the ILD layer 242 between the neighboring source/drain regions 236/238, the source/drain contact feature 266 across the neighboring source/drain regions 236/238 may be formed without complications from the additional dielectric materials, resulting in increased contact areas between the source/drain contact features 266 and the source/drain regions 236/238.

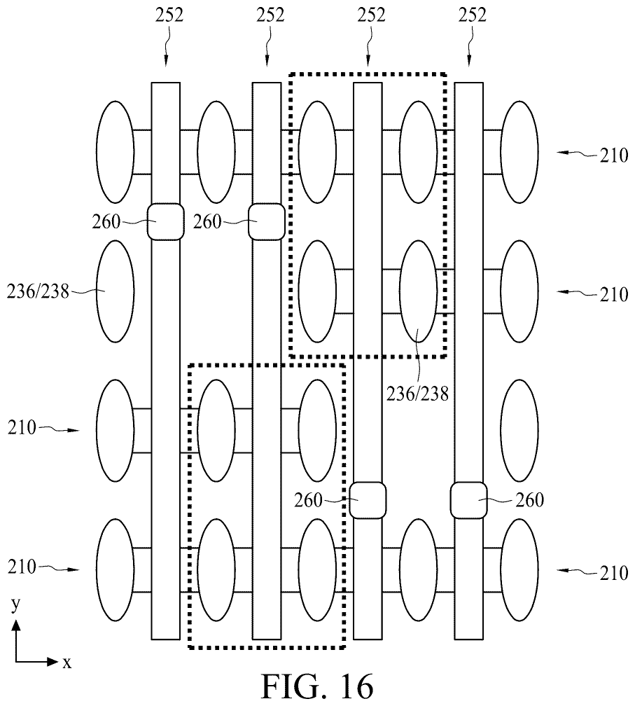

FIG. 16 is a schematic plan diagram of a SRAM (static random-access memory) device including via shaped cut gate structures 260 according to the present disclosure. The via-shaped cut gate structures 260 allowing the ILD layer to remain between source/drain regions adjacent to the via-shaped cut gate structures 260, marked in rectangles. The remaining ILD layer between the cut gate structures 260 minimizes parasitic capacitance in the SRAM device.

Via-shaped cut gate structures according to the present disclosure may be incorporated in any suitable semiconductor devices to reduce parasitic capacitance and improve product performance. For example the via shaped cut gate structures may be formed with FinFET devices, GAA or FinFET devices with or without hybrid fins, GAA or FinFET devices with SAC (self-aligned cap layer in the gate structures).

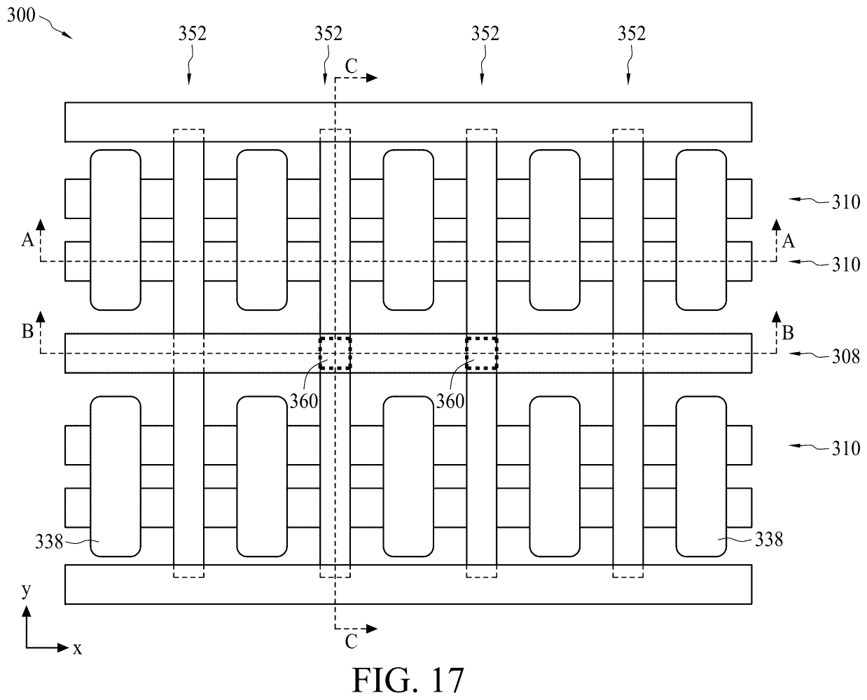

FIGS. 17, 18A-18C and 29A-29C schematically demonstrate a semiconductor device 300 according to present disclosure. The semiconductor device 300 is FinFET device with hybrid fins. In some embodiments, the semiconductor device 300 includes via-shaped cut gate structures formed over hybrid fins. The semiconductor device 300 may be fabricated according to the method 100.

FIG. 17 is a schematic plan view of the semiconductor device 300. As shown in FIG. 17, the semiconductor device 300 includes semiconductor fin structures 310 formed along the x-direction, gate structures 352 formed along the y-direction. Dielectric fins 308 are formed between the semiconductor fin structures 310. Source/drain regions 338 formed from the semiconductor fin structures 310. Via-shaped cut gate structures 360 are formed in the gate structures 352. In some embodiments, the via-shaped cut gate structures 360 are formed over the intersections of the gate structures 352 and the dielectric fins 308.

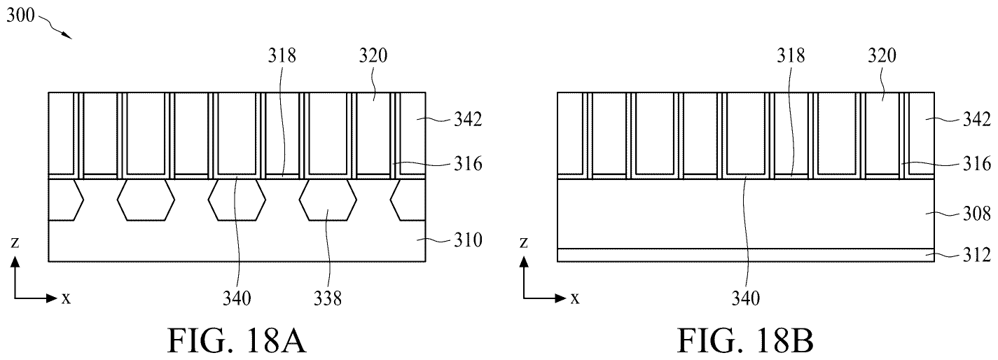

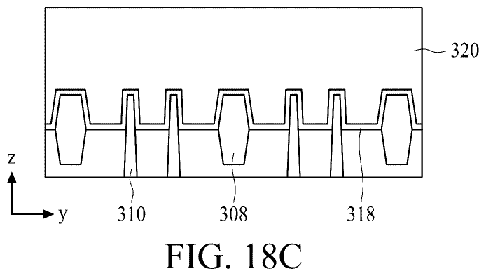

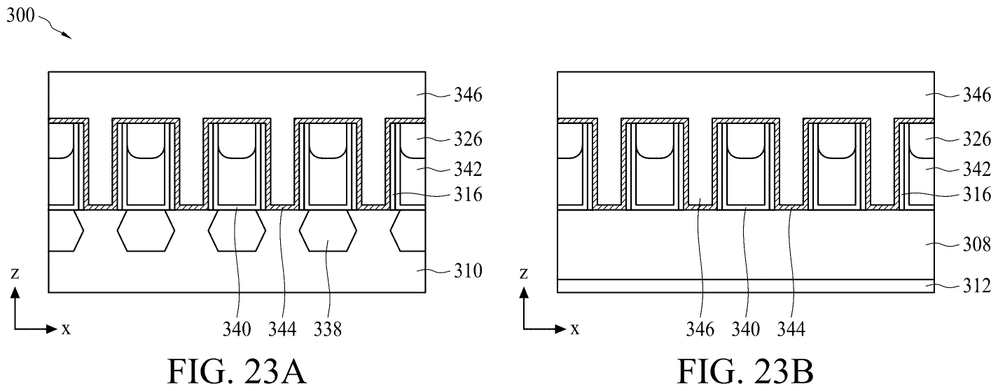

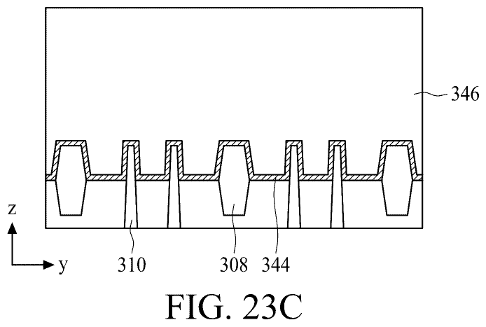

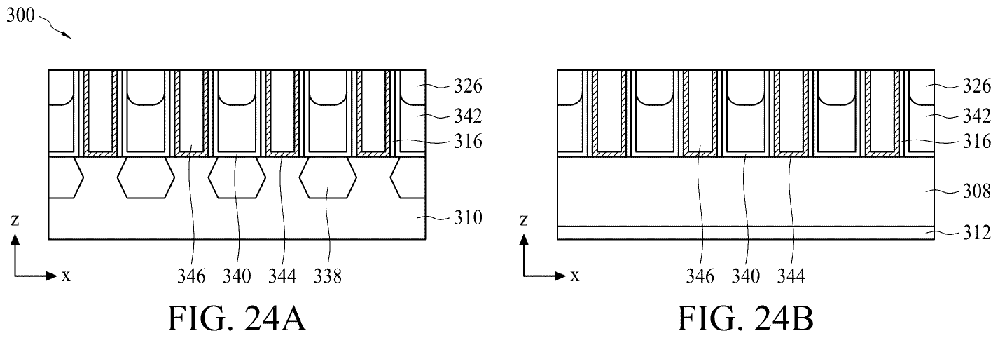

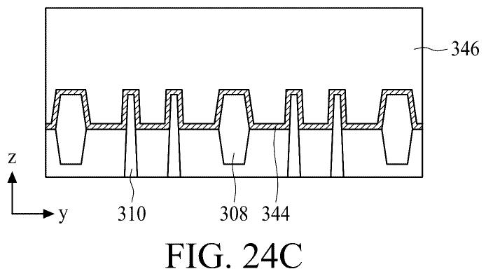

FIGS. 18A-18C to FIGS. 29A-29C schematic demonstrate the semiconductor devices at different stages of fabrication. FIGS. 18A-29A, 18B-29B, and 18C-29C are cross sectional views of the semiconductor device 300 along the lines A-A, B-B, and C-C in respectively FIG. 17.

FIGS. 18A-18C schematically illustrate the semiconductor device 300 after operation 112. In operation 102, the semiconductor fin structures 310 are formed on a semiconductor substrate 302. Isolation regions 312 are formed around the semiconductor fin structures 310. The dielectric fins 308 or hybrid fins extend from the isolation regions 312. The dielectric fins 308 may be formed from one or more dielectric materials and parallel to the semiconductor fin structures 310. In operation 104, sacrificial gate dielectric layer 318 and sacrificial gate electrode layers 320 are formed across the semiconductor fin structures 310 and the dielectric fins 308. In operation 106, gate sidewall spacers 316 are formed on sidewalls of the sacrificial gate structures. In operation 108, the semiconductor fin structures 310 not covered by the sacrificial gate structures are etched back and the source/drain regions 338 are formed therein. In operation 112, CESL 340 are deposited over the source/drain regions 338, the dielectric fins 308, and the gate sidewall spacers 316. An ILD layer 342 is then deposited over the CESL 340. A planarization process is then performed to expose the ILD layer 342 and the sacrificial gate electrode slayer 320.

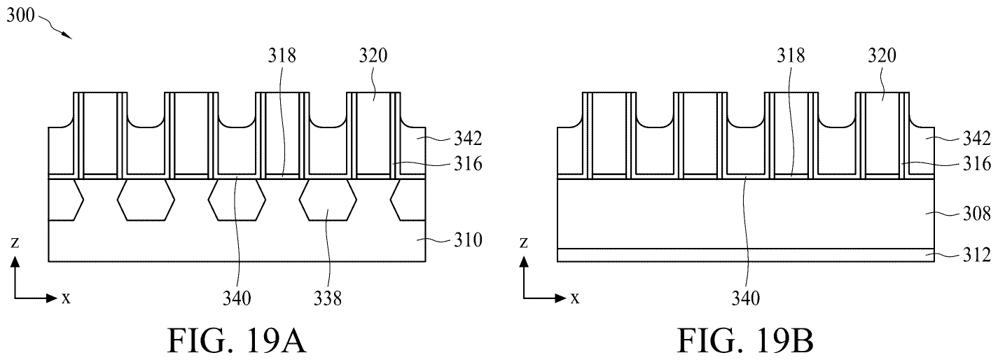

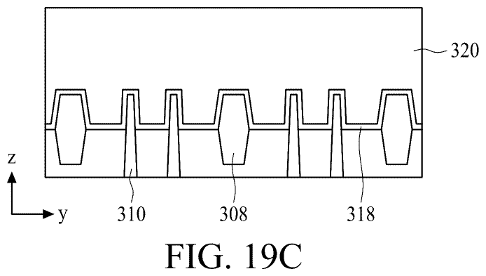

FIGS. 19A-19C schematically illustrate the semiconductor device 300 after operation 114, where the ILD layer 342 is etched back to a level lower than the sacrificial gate electrode layer 320.

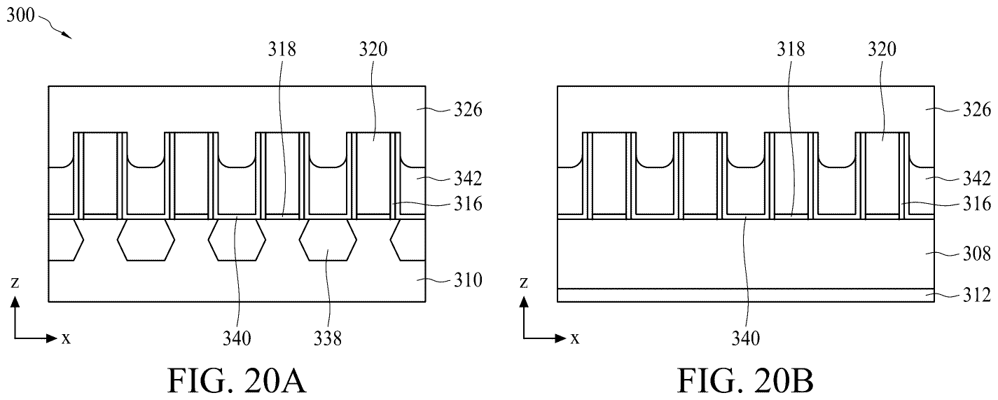

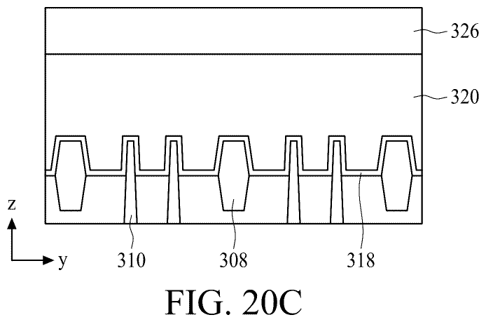

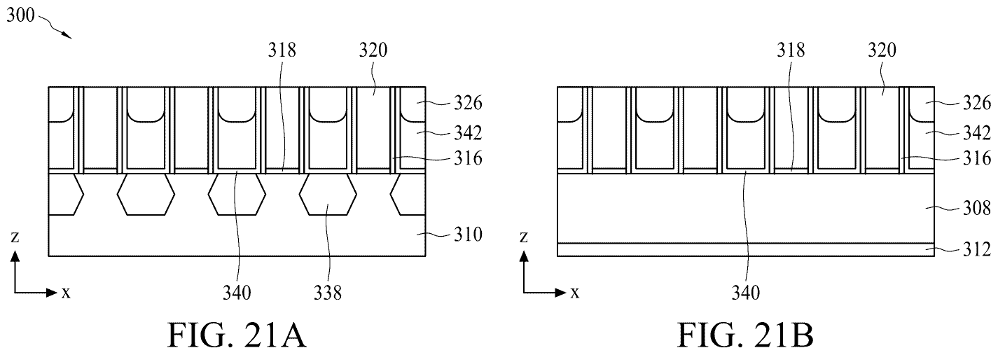

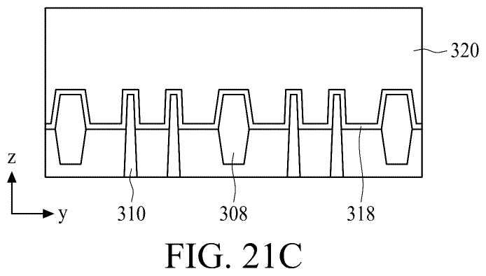

FIGS. 20A-20C and 21A-21C schematically illustrate the semiconductor device 300 after operation 116, where a protective material is deposited over the ILD layer 342, and then planarized to form the protective caps 326 over the ILD layer 342.

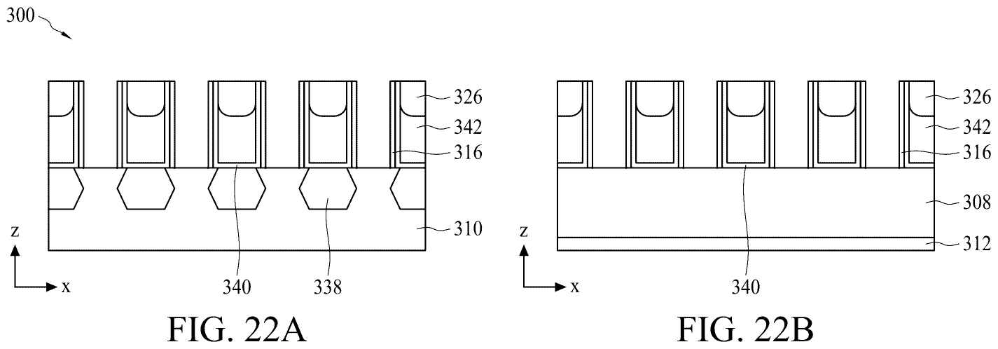

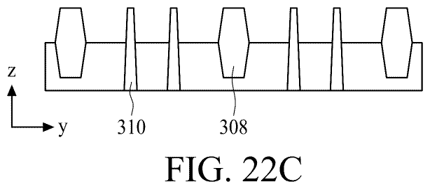

FIGS. 22A-22C, 23A-23C, and 24A-24C schematically illustrate the semiconductor device 300 after operation 118, where the replacement gate structures 352 are formed. A gate dielectric layer 344 is deposited over the semiconductor fin structures 310 and the dielectric fins 308, and the gate electrode layer 346 is deposited over the gate dielectric layer 344.

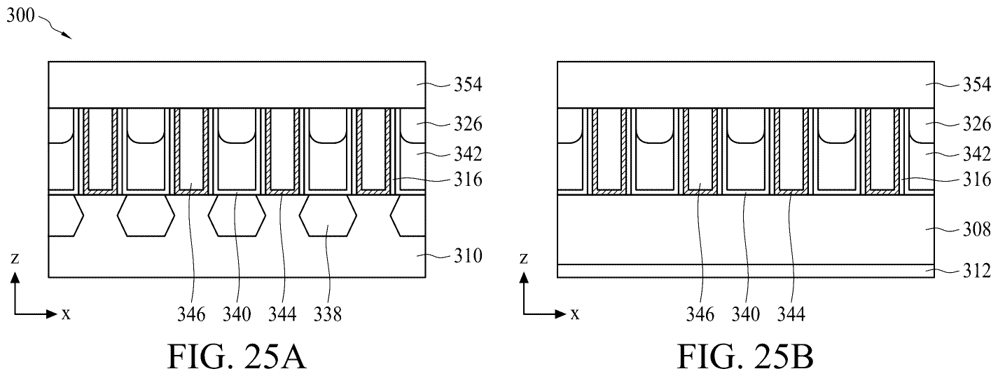

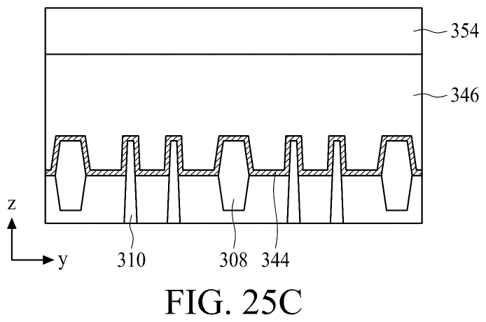

FIGS. 25A-25C schematically illustrate the semiconductor device 300 after operation 120, where a mask layer 354 is deposited over the protective caps 326 and the gate structures 352.

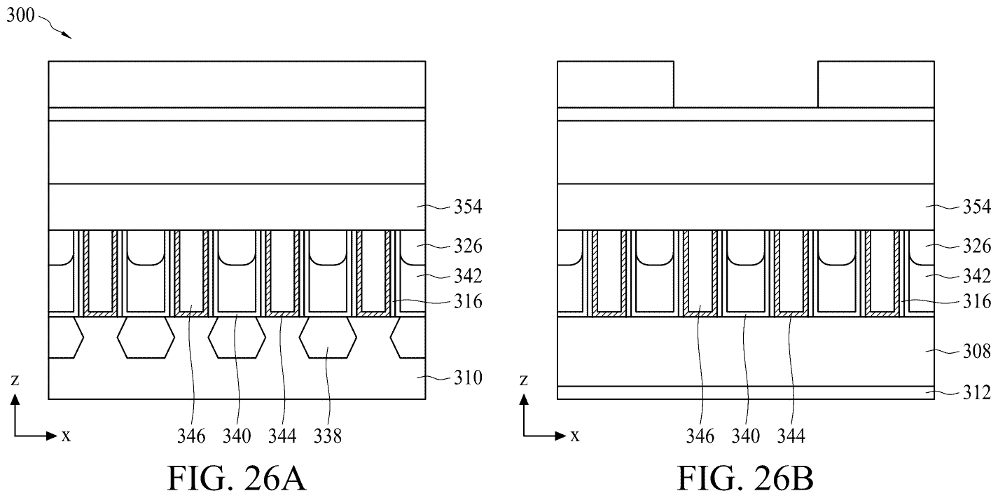

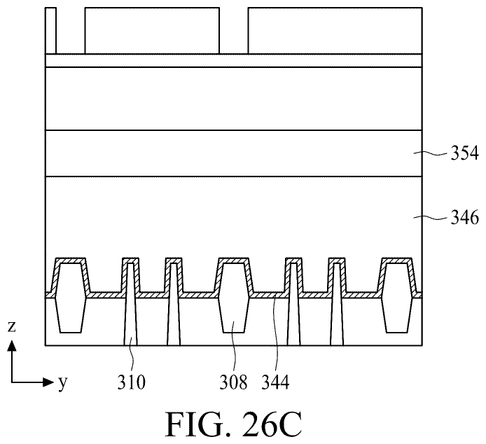

FIGS. 26A-26C schematically illustrate the semiconductor device 300 during operation 122, when a tri-layer photoresist layer is deposited over the hard mask layer 354 to form cut metal gate pattern in the hard mask layer 354.

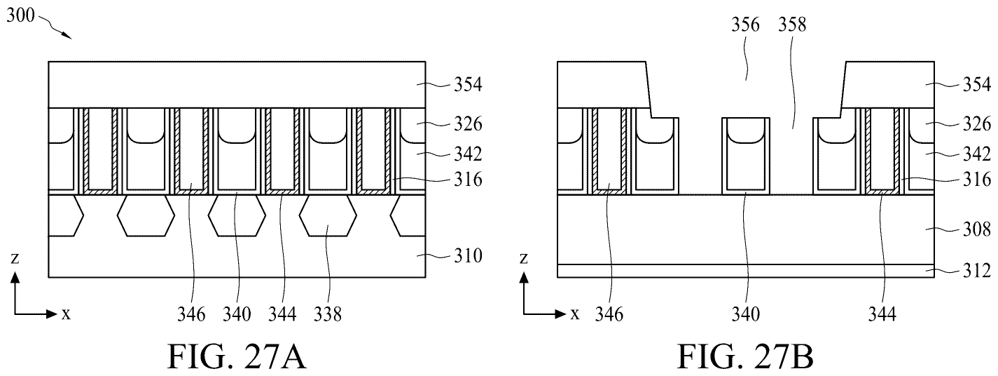

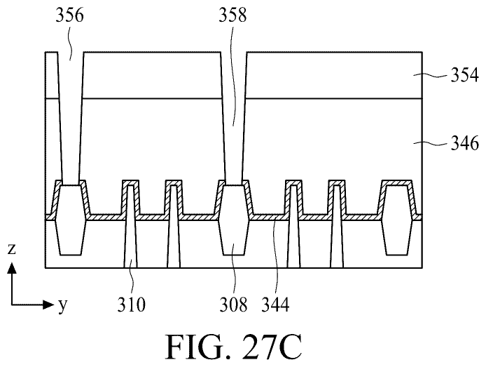

FIGS. 27A-27C schematically illustrate the semiconductor device 300 after operation 124, where cut gate openings 358 using cut gate pattern 356 in the mask layer 354. The cut gate openings 358 are formed by a self-aligned etch process using the cut gate pattern 356 formed in the mask layer 354.

The cut gate pattern 356 may include one or more elongated openings over the dielectric fins 308. The cut gate pattern 356 exposes one or more replacement gate structures 352 and the protective caps 326.

The cut gate openings 358 are vias formed through the replacement gate structures 352 and into the dielectric fins 308. In some embodiments, one or more etch processing may be performed to selectively remove the gate electrode layer 346 and the gate dielectric layer 344 exposed by the cut gate pattern 356 with the protective caps 326, the CESL 340, and the gate sidewall spacers 316 substantially unaffected. The cut gate openings 358 are via openings extended between the gate sidewall spacers 316 in the replacement gate structures 352. The cut gate openings 358 cut corresponding gate electrode layer 346 and gate dielectric layer 344 into segments within the replacement gate structure 352, as shown in FIG. 27C, while the ILD layer 324 under the openings of the cut gate pattern 356 remain. As shown in FIG. 27B, the cut gate openings 358 are formed between the gate sidewall spacers 316. In other words, the cut gate openings 358 do not extend through the gate sidewall spacers 316 along the X direction.

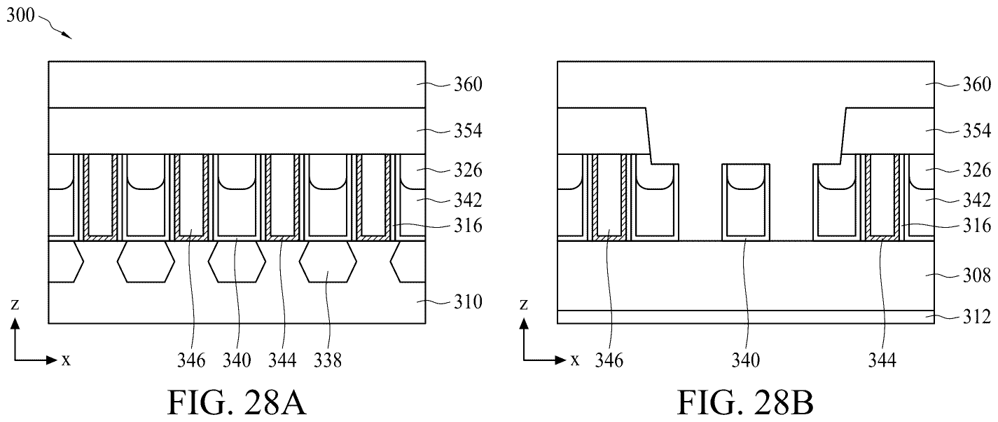

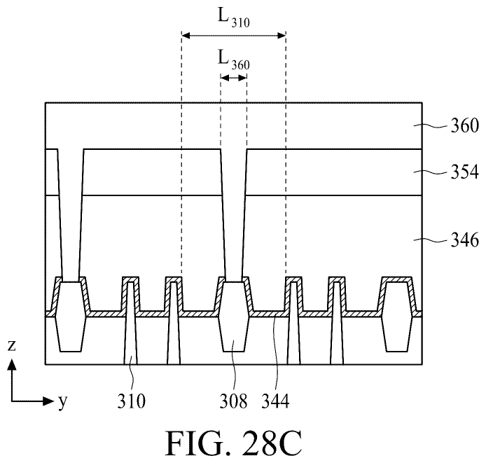

FIGS. 28A-28C schematically illustrate the semiconductor device 300 after operation 126, where the cut gate openings 358 are filled with the dielectric material forming the cut gate structures 360. In some embodiments, the cut gate structure 360 may include silicon nitride, silicon oxide, or a combination.

The cut gate structures 360 are via structures limited within the gate sidewall spacers 316 without extending into the ILD layer 342. The cut gate structure 360 cuts through the gate electrode layer 346 and the gate dielectric layer 344 and into the dielectric fins 308. In some embodiments, the cut gate structure 360 has a width along the x direction. The width of the cut gate structure 360 is equal to the distance between the gate sidewall spacers 316 along the x-direction. In some embodiments, the cut gate structure 360 has a length along the y direction. In some embodiments, the length of the cut gate structure 360 is in a range between about 5 nm and about 20 nm. A length less than about 5 nm may not be sufficient enough to provide electric isolation between the gate electrode layer 346 on opposite sides of the cut gate structure 360. A length greater than 20 nm may affect structure integrity of the adjacent semiconductor fin structures 310. In some embodiments, the length of the cut gate structure 360 along the Y-direction is about 20 percent to about 90 percent of a length L₃₁₀ between two adjacent semiconductor fin structures 310. The cut gate structure 360 extends into the dielectric fins 308 for a depth D₃₆₀ along the z direction. In some embodiments, the depth D₃₆₀ is in a range between about 3 nm and about 70 nm, which depends on the material of the dielectric fins 308. In general, the bottom of the cut gate structure 360 should be above the isolation region 312, therefore the well structure in the substrate 302 below the isolation region 312 is not damaged by cut gate processes.

By limiting the cut gate structures 360 within the replacement gate structures 352, embodiments of the present disclosure avoid forming a dielectric structure between neighboring epitaxial source/drain regions 338 and minimizing parasite capacitance within the semiconductor device 300.

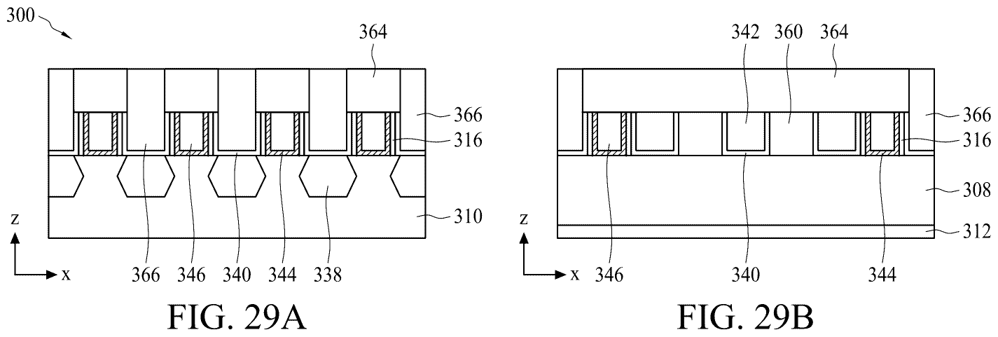

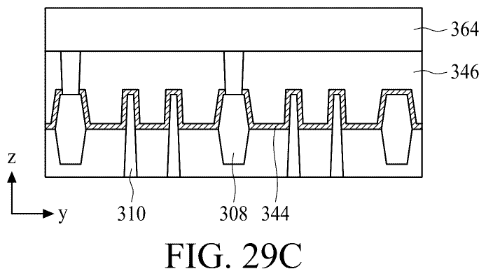

FIGS. 29A-29C schematically illustrate the semiconductor device 300 after operation 128, where source/drain contact features 366 are formed. After deposition of the dielectric filling material, a planarization process may be performed to expose the gate electrode layer 346 and the ILD layer 342 for the subsequent process. The protective caps 326 are removed during the planarization process. In some embodiments, an ILD layer 364 may then deposited over the gate electrode layer 346 and the ILD layer 342.

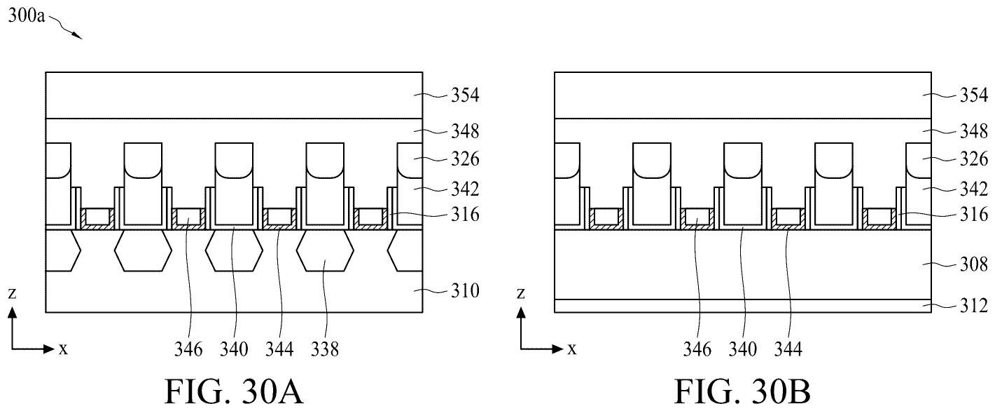

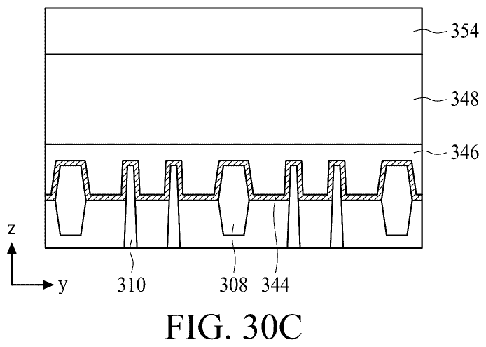

FIGS. 30A-30C to FIGS. 33A-33C schematic demonstrate the semiconductor device 300a at different stages of fabrication. The semiconductor device 300a is similar to the semiconductor device 300 described above except that the semiconductor device 300a includes a SAC layer 348 formed over the gate structures 352. FIGS. 30A-33A, 30B-33B, and 30C-33C are cross sectional views of the semiconductor device 300 along the lines A-A, B-B, and C-C in respectively FIG. 17.

FIGS. 30A-30C schematically illustrate the semiconductor device 300a after operation 118, where the replacement gate structures 352 are formed. In operation 118, the gate dielectric layer 344 is deposited over the semiconductor fin structures 310 and the dielectric fins 308, and the gate electrode layer 346 is deposited over the gate dielectric layer 344. A planarization process may be performed to expose the protective caps 326 after deposition of the gate electrode layer 346. The gate electrode layer, the gate structures 352 are selectively recessed to form a self-aligned cap (SAC) recess. A dielectric material for the SAC layer 348 is then deposited. The SAC layer 348 may be deposited by any suitable process, such as CVD, PECVD, or a suitable deposition process. The dielectric material for the SAC layer 348 may include silicon oxide, silicon nitride, silicon carbide, silicon carbonitride, silicon oxynitride, silicon oxycarbonitride, aluminum oxide, aluminum nitride, aluminum oxynitride, zirconium oxide, zirconium nitride, zirconium aluminum oxide, hafnium oxide, or a suitable dielectric material. The hard mask layer 354 is then deposited on the SAC layer 348.

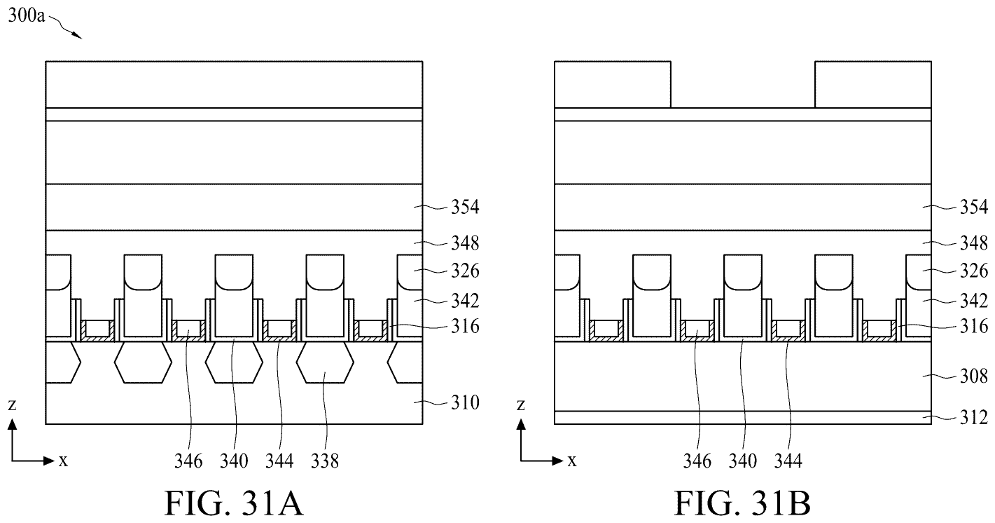

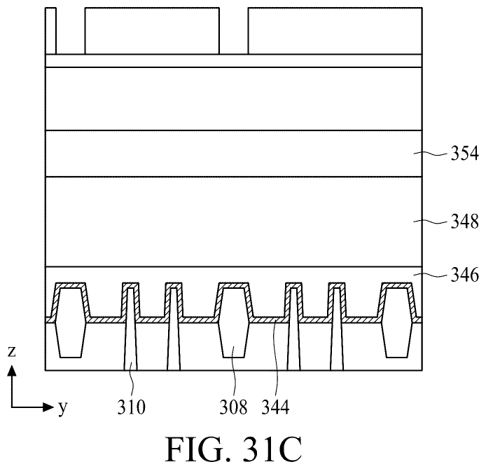

FIGS. 31A-31C schematically illustrate the semiconductor device 300a during operation 122, when a tri-layer photoresist layer is deposited over the hard mask layer 354 to form cut metal gate pattern in the hard mask layer 354.

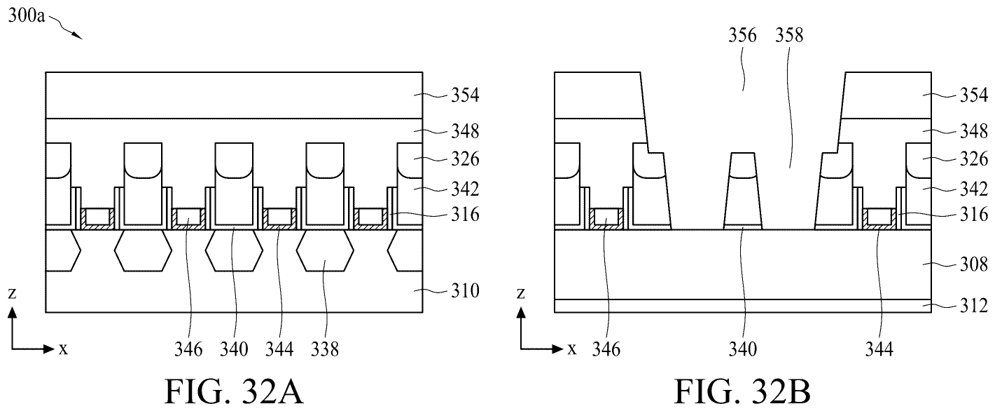

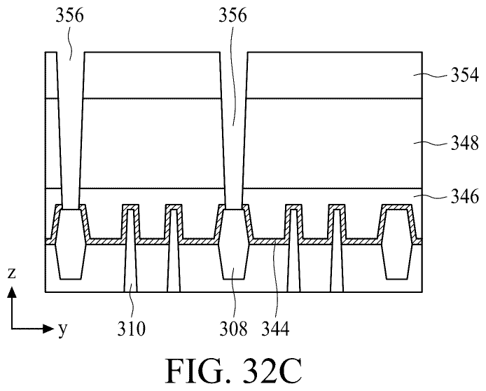

FIGS. 32A-32C schematically illustrate the semiconductor device 300a after operation 124, where cut gate openings 358 using cut gate pattern 356 in the mask layer 354. The cut gate openings 358 are formed by a self-aligned etch process using the cut gate pattern 356 formed in the mask layer 354. The cut gate openings 358 are via openings formed through the SAC layer 348, the gate electrode layer 346, the gate dielectric layer 344 and into the dielectric fins 308.

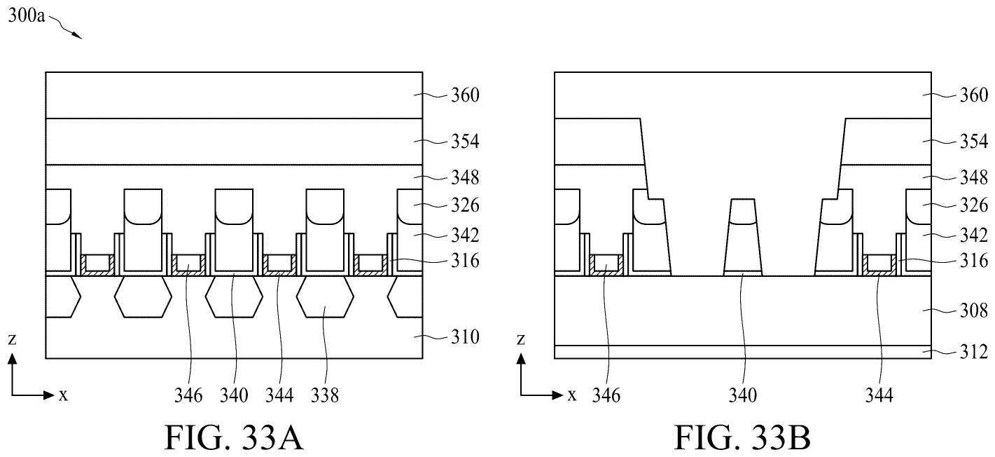

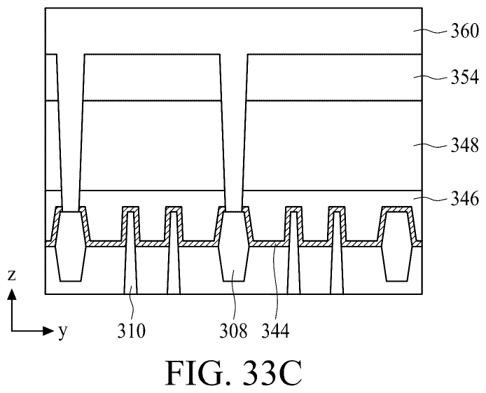

FIGS. 33A-33C schematically illustrate the semiconductor device 300a after operation 126, where the cut gate openings 358 are filled with the dielectric material forming the cut gate structures 360. In some embodiments, the cut gate structure 360 may include silicon nitride, silicon oxide, or a combination.

The cut gate structures 360 are via structures limited within the gate sidewall spacers 316 without extending into the ILD layer 342. The cut gate structure 360 cuts through the SAC layer 348, the gate electrode layer 346 and the gate dielectric layer 344 and into the dielectric fins 308.

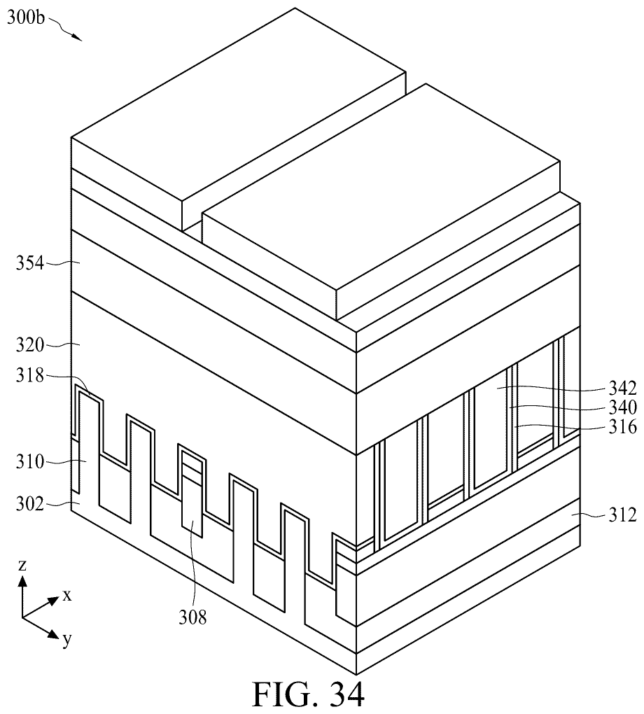

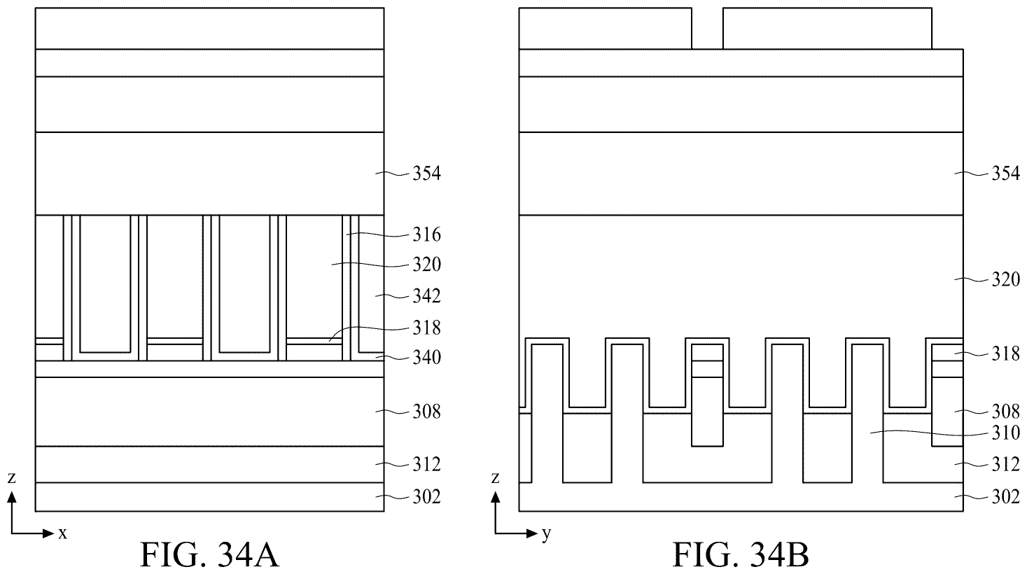

In some embodiments, the via-shaped cut gate structures according to the present disclosure may also be used in cut poly gate process, i.e. to form the cut gate structures before forming the replacement structure. During cut poly gate process, a portion of sacrificial gate structure, i.e. polysilicon layer, is selectively removed from the ILD layer without using the protective caps. A cut poly gate process according to present disclosure using the method 100 by omitting the operation 112, 114, 116 and performing operation 118 after operation 126. FIGS. 34, 34A-34B, 35, 35A-35B, 36, 36A-36B, 37, 37A-37B, and 38A-38B demonstrate a semiconductor device 300b at different stages of fabrication. The semiconductor device 300a is similar to the semiconductor device 300 described above except that the semiconductor device 300b includes via-shaped cut gate structure 360b formed during a cut poly gate process.

FIGS. 34, 34A-34B schematically illustrate the semiconductor device 300b after operation 112. FIG. 34 is a schematic perspective view of the semiconductor device 300b. FIG. 34A is a cross sectional view of the semiconductor device 300b along a dielectric fin 308. FIG. 34B is a cross sectional view of the semiconductor device 300b along a gate structure. In operation 112, the CESL 340 is deposited over the source/drain region 338, the gate sidewall spacers 316, the isolation region 312, and the dielectric fins 308.

After operation 112, operations 120 is performed to deposit a mask layer 354 over the sacrificial gate layers 320, 318 and the ILD layer 342 as shown in FIG. 34. FIG. 34, 34A-34B further illustrate a tri-layer photoresist layer deposited over the hard mask layer 354 to form cut metal gate pattern in the hard mask layer 354.

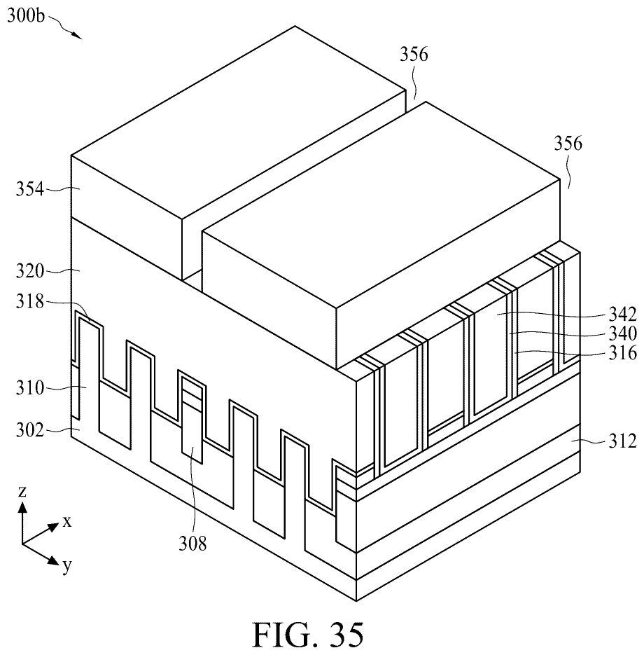

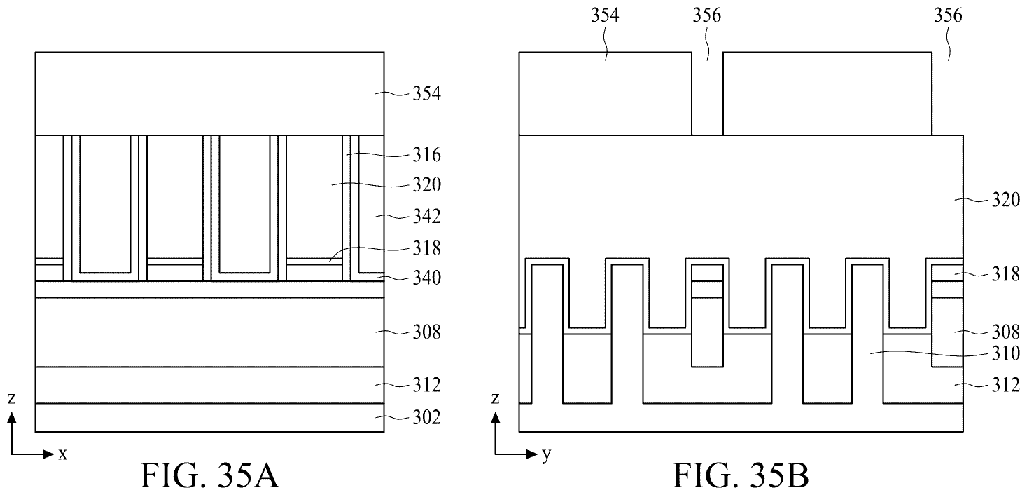

FIGS. 35, 35A-35B schematically illustrate the semiconductor device 300b after operation 122, where cut gate openings 358 using cut gate pattern 356 in the mask layer 354. The cut gate openings 358 are formed by a self-aligned etch process using the cut gate pattern 356 formed in the mask layer 354. The cut gate pattern 356 may include one or more elongated openings over the dielectric fins 308. The cut gate pattern 356 expose one or more the sacrificial gate structure, i.e. the sacrificial gate electrode layer 320 and the ILD layer 342.

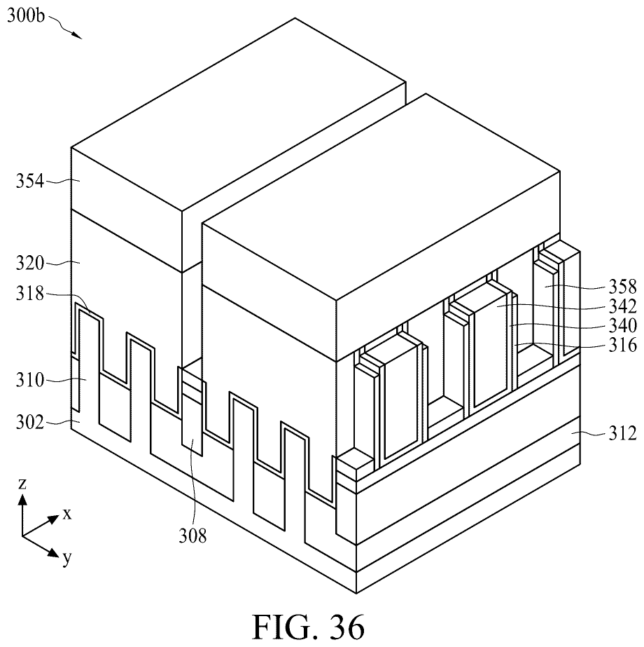

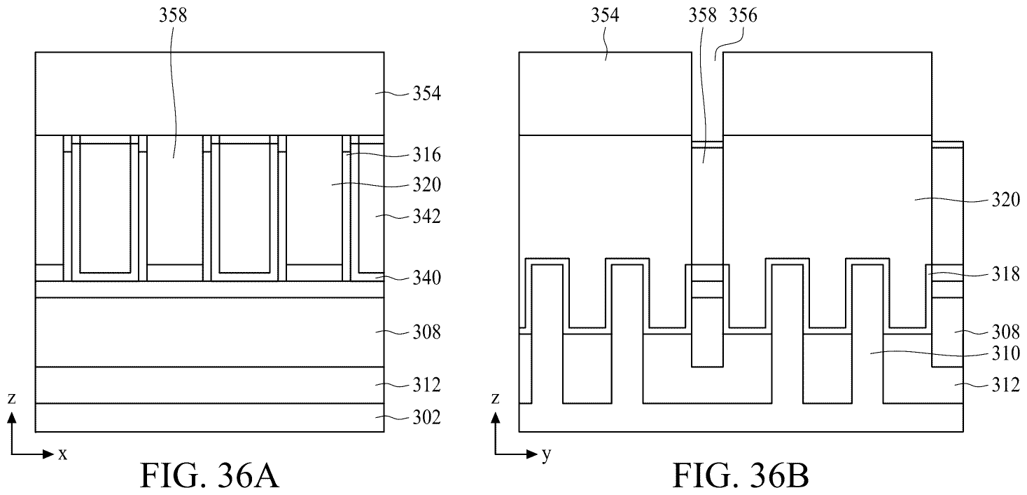

FIGS. 36, 36A-36B schematically illustrate the semiconductor device 300b after operation 124, where cut gate openings 358 using cut gate pattern 356 in the mask layer 354. The cut gate openings 358 are formed by a self-aligned etch process using the cut gate pattern 356 formed in the mask layer 354. In some embodiments, a dry etch process to selectively remove the exposed sacrificial gate electrode layer 320 and the sacrificial gate dielectric layer 318 with the exposed ILD layer 342 substantially unaffected. In some embodiments, the operation 124 may be an etch process using an etch chemistry comprising etchants such as Cl₂ or HBr based chemistry with O₂ or CO₂ addition.

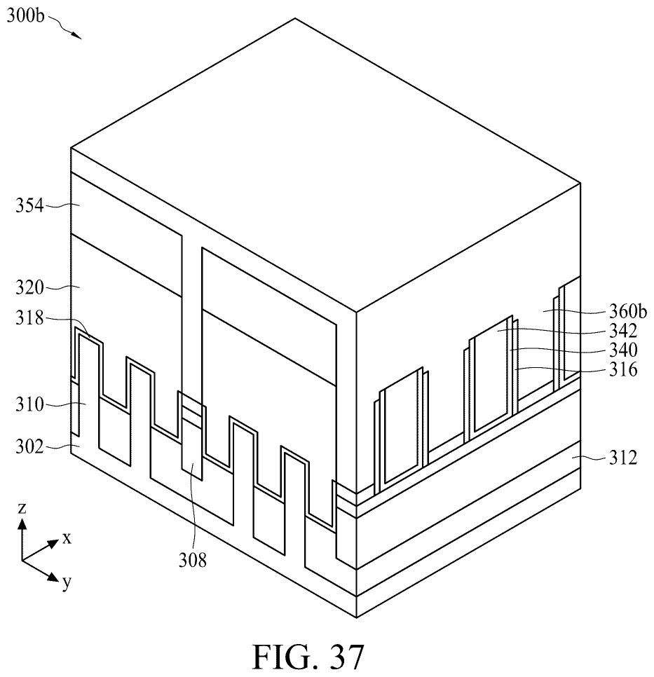

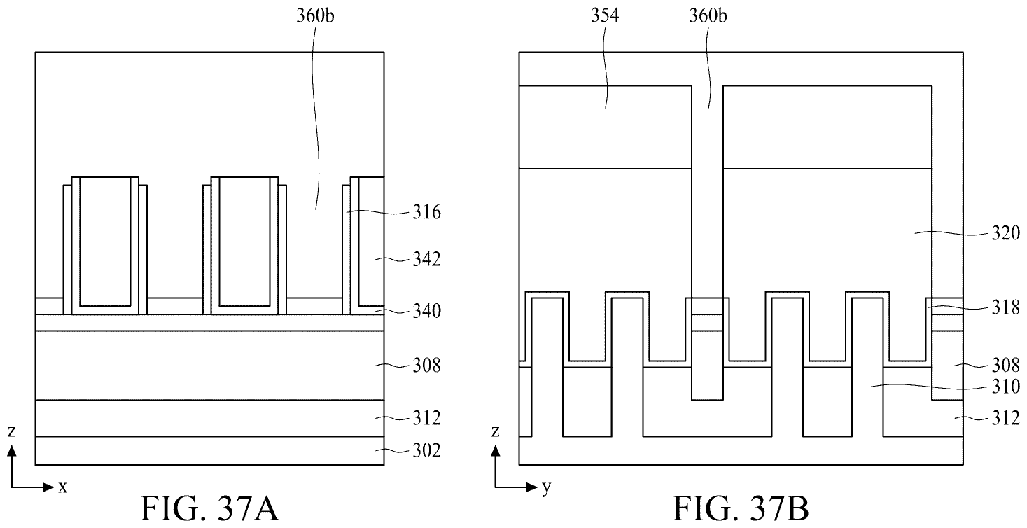

FIGS. 37, 37A-37B schematically illustrate the semiconductor device 300b after operation 126, where the cut gate openings 358 are filled with the dielectric material forming the cut gate structures 360b. In some embodiments, the cut gate structure 360 may include silicon nitride, silicon oxide, or a combination.

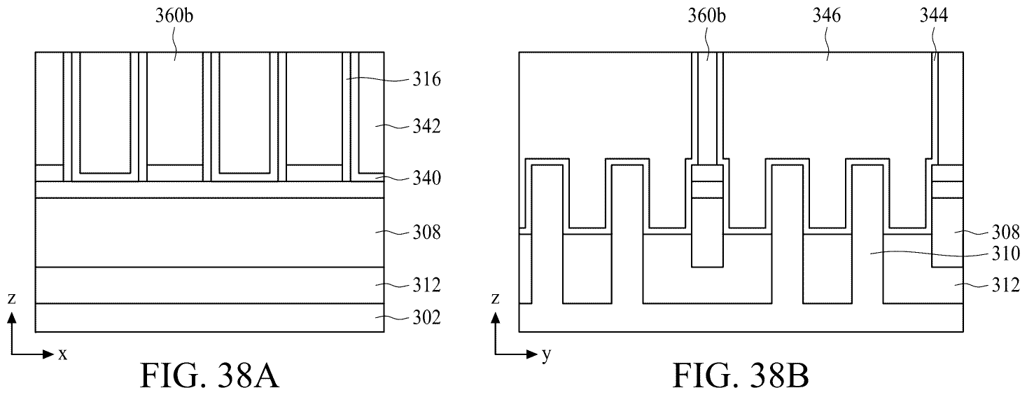

After operation 126, the replacement gate process, such as operation 118, is performed to form the gate dielectric layer 344 and the replacement gate electrode layer 346. FIGS. 38A-38B schematically illustrate the semiconductor device 300b after the replacement gate process. As shown in FIG. 38B, the cut gate structures 360b are via structures limited within the gate sidewall spacers 316 without extending into the ILD layer 342. The cut gate structure 360b is in contact with the gate dielectric layer 344. The cut gate structures 360b are via-shaped dielectric structures defined by the gate sidewall spacers 316 and the gate dielectric layer 344. In some embodiments, the cut gate structures 306b may extend into the dielectric fin 308 if present or into the isolation region 312 when the dielectric fin 30 is not present.

Various embodiments or examples described herein offer multiple advantages over the state-of-art technology. Embodiments of the present disclosure provide a semiconductor device with via-shaped cut gate structures, which is defined within sidewall spacers in the gate structures. Because the via-shaped cut gate structures do not extend between adjacent source/drain regions, thereby, minimizing parasitic capacitance formed between the source/drain regions. The via-shaped cut gate structures may be fabricated using the existing circuit design, therefore, easily adopted.

Some embodiments of the present provide a method comprising: forming a semiconductor structure comprising: first and second semiconductor fin structures extending a first direction; a gate structure across the first and second semiconductor fin structures; a first source/drain region on the first semiconductor fin structure; a second source/drain region on the second semiconductor fin structure; and an ILD (interlayer dielectric) layer over the first and second source/drain regions; depositing a mask layer over the semiconductor structure; forming a first opening through the mask layer, wherein the first opening extends along the first direction disposed between the first and second semiconductor fin structures, and the first opening exposes a portion of the gate structure and the ILD layer; forming a via opening in the gate structure through the first opening in the mask layer, wherein the via opening divides the gate structure into two segments; filling a dielectric material in the via opening to form a cut gate structure.

Some embodiments of the present disclosure provide a semiconductor device, comprising: first and second semiconductor fin structures extending a first direction; and a gate structure across the first and second semiconductor fin structures, wherein the gate structure comprises: a first gate segment disposed over the first semiconductor fin structure; a second gate segment dispose over the second semiconductor fin structure; a cut gate structure disposed between the first and second gate segments; a first gate sidewall spacer; and a second gate sidewall spacer, wherein the cut gate structure is disposed between the first and second gate sidewall spacers.

Some embodiments of the present disclosure provide a semiconductor device, comprising: a first gate structure; a second gate structure parallel to the first gate structure; a first source/drain region formed between the first and second gate structures; a second source/drain region formed between the first and second gate structures; a source/drain contact feature in contact with the first and second source/drain regions; a first cut gate structure disposed in the first gate structure; a second cut gate structure disposed in the second gate structure; a first dielectric layer disposed between the source/drain contact feature and the first cut gate structure; and a second dielectric layer disposed between the source/drain contact feature and the second cut gate structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method, comprising:
forming a semiconductor structure comprising:
first and second semiconductor fin structures extending along a first direction;
a gate structure across the first and second semiconductor fin structures;
a first source/drain region on the first semiconductor fin structure;
a second source/drain region on the second semiconductor fin structure; and
an ILD (interlayer dielectric) layer over the first and second source/drain regions;
depositing a mask layer over the semiconductor structure;
forming a first opening through the mask layer, wherein the first opening extends along the first direction disposed between the first and second semiconductor fin structures, and the first opening exposes a portion of the gate structure and the ILD layer;
forming a via opening in the gate structure through the first opening in the mask layer, wherein the via opening divides the gate structure into two segments;
filling a dielectric material in the via opening to form a cut gate structure.

2. The method of claim 1, wherein the semiconductor structure further comprises a first gate sidewall spacer and a second gate sidewall spacer disposed on sidewalls of the gate structure, and the cut gate structure is in contact with the first gate sidewall spacer and the second gate sidewall spacer.

3. The method of claim 1, further comprising forming a protective cap over the ILD layer prior to depositing the mask layer.

4. The method of claim 3, wherein forming the protective cap comprises:
recessing the ILD layer to a level below the gate structure;
depositing a protective material over the semiconductor structure; and
planarizing the semiconductor structure to expose the gate structure.

5. The method of claim 4, wherein the protective material is a nitrogen containing dielectric material.

6. The method of claim 3, further comprising, after filling the dielectric material in the via opening, planarizing the semiconductor structure to remove the protective cap.

7. The method of claim 1, further comprising, after filling the dielectric material in the via opening:
removing the two segments of the gate structure to expose the first semiconductor fin structure and the second semiconductor fin structure;
depositing a replacement gate dielectric layer on the first semiconductor fin structure and the second semiconductor fin structure; and
depositing a replacement gate electrode layer on the replacement gate dielectric layer.

8. The method of claim 1, wherein the semiconductor structure further comprises a dielectric fin disposed between the first and second semiconductor fin structures, and the via opening extends into the dielectric fin.

9. The method of claim 1, wherein the semiconductor structure further comprise an isolation layer disposed under the gate structure, and the via opening extends into the isolation layer.

10. A semiconductor device, comprising:
first and second semiconductor fin structures extending along a first direction; and
a gate structure across the first and second semiconductor fin structures, wherein the gate structure comprises:
a first gate segment disposed over the first semiconductor fin structure;
a second gate segment dispose over the second semiconductor fin structure;
a cut gate structure disposed between the first and second gate segments;
a first gate sidewall spacer; and
a second gate sidewall spacer, wherein the cut gate structure is disposed between the first and second gate sidewall spacers.

11. The semiconductor device of claim 10, further comprising:
a dielectric fin disposed between the first and second semiconductor fin structure, wherein the gate structure is disposed over the dielectric fin, and the cut gate structure extends into the dielectric fin.

12. The semiconductor device of claim 10, further comprising:
an isolation layer disposed around the first and second semiconductor fin structures, wherein the gate structure is disposed over the isolation layer, and the cut gate structure extends into the isolation layer.

13. The semiconductor device of claim 10, further comprising:
a first source/drain region on the first semiconductor fin structure;
a second source/drain region on the second semiconductor fin structure; and
an ILD (interlayer dielectric) layer over the first and second source/drain regions, wherein the first gate sidewall spacer is disposed between the ILD layer and the cut gate structure.

14. The semiconductor device of claim 13, further comprising:
a CESL (contact etch stop layer) disposed between the ILD layer and the first gate sidewall spacer.

15. The semiconductor device of claim 10, wherein the first gate segment comprises:
a gate dielectric layer; and
a gate electrode layer, wherein the gate electrode layer is in contact with the cut gate structure.

16. The semiconductor device of claim 10, wherein the first gate segment comprises:
a gate dielectric layer; and
a gate electrode layer, wherein the gate dielectric layer is disposed between the gate electrode layer and the cut gate structure.

17. A semiconductor device, comprising:
a first gate structure;
a second gate structure parallel to the first gate structure;
a first source/drain region formed between the first and second gate structures;
a second source/drain region formed between the first and second gate structures;
a source/drain contact feature in contact with the first and second source/drain regions;
a first cut gate structure disposed in the first gate structure;
a second cut gate structure disposed in the second gate structure;
a first dielectric layer disposed between the source/drain contact feature and the first cut gate structure; and
a second dielectric layer disposed between the source/drain contact feature and the second cut gate structure.

18. The semiconductor device of claim 17, wherein the first dielectric layer comprises a first gate sidewall spacer in contact with the first gate structure.

19. The semiconductor device of claim 18, wherein the first dielectric layer further comprises a CESL (contact etch stop layer) in contact with the first and second source/drain regions.

20. The semiconductor device of claim 19, further comprising an isolation layer, wherein the first gate structure is disposed on the isolation layer, and the first cut gate structure extends into the isolation layer.
